(19) United States
(12) Patent Application Publication
(10) Pub. No.: US 2022/0389268 A1
(43) Pub. Date: Dec. 8, 2022

(54) INK-JET APPLICATION TYPE COMPOSITION FOR WIRING-LINE PROTECTION, METHOD FOR PRODUCING SEMICONDUCTOR DEVICE USING SAME, AND SEMICONDUCTOR DEVICE

(71) Applicant: Mitsui Chemicals, Inc., Tokyo (JP)

(72) Inventors: Yasuharu YAMADA, Kawasaki-shi, Kanagawa (JP); Takumi SHIRAISHI, Narashino-shi, Chiba (JP); Yusuke TOMITA, Kisarazu-shi, Chiba (JP); Yugo YAMAMOTO, Chiba-shi, Chiba (JP); Takuo SHIKAMA, Chiba-shi, Chiba (JP)

(21) Appl. No.: 17/772,123

(22) PCT Filed: Oct. 27, 2020
(86) PCT No.: PCT/JP2020/040198

§ 371 Date: Apr. 26, 2022

(30) Foreign Application Priority Data
Oct. 29, 2019 (JP) 2019-196090
Dec. 9, 2019 (JP) 2019-222142

(51) Int. Cl. C09D 163/00; C08G 59/24; H05K 3/28; C08G 59/68

(52) U.S. Cl. CPC C09D 163/00; C08G 59/24; H05K 3/28; C08G 59/68

(57) ABSTRACT

The present invention addresses the problem of providing an ink-jet application type composition for wiring-line protection which can form layers that are excellent in terms of pattern retentivity and moisture resistance at high temperatures, have satisfactory adhesiveness to the circuits or metal wiring lines of the semiconductor device over a long period, and are less apt to suffer ion migration. The ink-jet application type composition for wiring-line protection comprises (A) one or more cationic photopolymerizable compounds including an alicyclic epoxy compound, (B) a cationic photopolymerization initiator, and (C) a silane coupling agent, wherein the silane coupling agent is contained in an amount of 1-50 parts by mass per 100 parts by mass of the cationic photopolymerizable compounds. The ink-jet application type composition for wiring-line protection has a viscosity, as measured with an E-type viscometer at 25° C. and 20 rpm, of 5-50 mPa·s.

### TECHNICAL FIELD

The present invention relates to an inkjet coating-type composition for protecting wiring (hereinafter also referred to as “inkjet coating-type wiring protection composition”), a method for producing a semiconductor device using the composition, and a semiconductor device.

### BACKGROUND ART

Conventionally, a polyimide layer has been widely used as a protective layer for protecting a semiconductor. In recent years, the configuration of semiconductor devices has become complicated, which requires, for example, forming of a protective layer, an insulating layer, and the like of a semiconductor device in a pattern. For forming a conventional polyimide layer in a pattern, polyimide or the precursor thereof is applied to the entire surface by a spin coating method and cured. It is common practice after the spin coating to process the obtained layer into a desired pattern by photolithography, etching, or the like. However, such a method is complicated and time-consuming. In addition, as a part of a resin composition is removed by the etching or the like, the efficiency of material utilization is low. There is thus a demand for a simpler method to form the protective layer and the insulating layer of a semiconductor device, and the like in a pattern.

Recently, cationically polymerizable compositions containing epoxy resins have been proposed as various adhesives, sealing agents, potting agents, coating agents, and the like (Patent Literature (hereinafter abbreviated as “PTL”) 1). In addition, a resin composition containing a silicon compound has also been proposed as a resist for nanoimprinting (PTL 2).

### CITATION LIST

### Patent Literature

### PTL 1

WO2017/094584

### PTL 2

Japanese Patent No. 5757242

### SUMMARY OF INVENTION

### Technical Problem

As a method of forming a protective layer or an insulating layer of a semiconductor device or the like in a pattern, it is conceivable, for example, to apply a composition by an inkjet method. However, a conventional resin composition containing polyimide is difficult to use for an inkjet method due to its high viscosity. It is also conceivable to apply a cationically polymerizable composition described in PTL 1 or the like by an inkjet method. However, the cationically polymerizable composition of PTL 1 has a high viscosity and is not suitable for application by an inkjet method. In addition, the cured product of the cationically polymerizable composition of PTL 1 is easily peeled off over time when used under high temperature and high humidity. The present inventors have also found that a cationically polymerizable composition containing a common epoxy resin as described in PTL 1 tend to contain chlorine derived from the material (especially epoxy resins), and when such a cationically polymerizable composition is used for the protective layer or insulating layer of a semiconductor device, or the like, chlorine ions migrate and easily cause corrosion of metal wiring or the like.

It is also conceivable to apply the resin composition described in PTL 2 by an inkjet method, but this resin composition also has a high viscosity and is not suitable for printing by an inkjet method.

An object of the present invention is to provide an inkjet coating-type wiring protection composition having the following features: having excellent pattern retention and moisture resistance at high temperatures; having suitable adhesion to, for example, wiring of a semiconductor device for a long period of time; capable of forming a layer that is less likely to cause ion migration; and applicable by an inkjet method.

### Solution to Problem

The present invention provides an inkjet coating-type wiring protection composition as follows.

[1] An inkjet coating-type wiring protection composition, containing: a photocationically polymerizable compound (A) that contains an alicyclic epoxy compound having two or more epoxy groups per molecule; a photocationic polymerization initiator (B); and a silane coupling agent (C), in which the silane coupling agent (C) is contained in an amount of 1 to 50 parts by mass based on 100 parts by mass of the photocationically polymerizable compound (A), and the inkjet coating-type wiring protection composition has a viscosity of 5 to 50 mPa·s measured at 25° C. and 20 rpm by using an E-type viscometer.
[2] The inkjet coating-type wiring protection composition according to [1], in which: the inkjet coating-type wiring protection composition has a surface tension of 20 to 40 mN/m.
[3] The inkjet coating-type wiring protection composition according to [1] or [2], in which: the alicyclic epoxy compound has a cycloalkene oxide structure represented by the following general formula

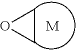

where M represents an alicyclic structure having 4 to 8 carbon atoms.

The present invention provides a cured product and a semiconductor device as follows.

[4] A cured product of the inkjet coating-type wiring protection composition according to any one of [1] to [3], in which:

the cured product has a loss tangent (tan δ) of 0.01 or more in a temperature range of 25° C. to 150° C. when dynamic viscoelasticity measurement is performed at a frequency of 1.6 Hz.

[5] A semiconductor device, including: a semiconductor circuit board or a board including metal wiring, the semiconductor circuit board including a circuit on at least one surface thereof; and a cured product layer that covers the semiconductor circuit board or the metal wiring of the board, in which the cured product layer contains a polymer and a silane coupling agent, the polymer being a polymer of a photocationically polymerizable compound containing an alicyclic epoxy compound having two or more epoxy groups per molecule, and the silane coupling agent is contained in an amount of 1 to 50 parts by mass based on 100 parts by mass of the polymer.

The present invention also provides a method for producing a semiconductor device as follows.

[6] A method for producing a semiconductor device, the method including: preparing a semiconductor circuit board or a board including metal wiring, the semiconductor circuit board including a circuit on at least one surface thereof; applying the inkjet coating-type wiring protection composition according to any one of [1] to [3] on the circuit of the semiconductor circuit board or on the metal wiring of the board by an inkjet method; photo curing of curing a coating film of the inkjet coating-type wiring protection composition by irradiating the coating film with active light within 60 seconds after the applying; and thermal curing of curing the coating film after the photo curing with heat.

The present invention further provides an inkjet coating-type wiring protection composition as follows.

[7] An inkjet coating-type wiring protection composition, containing: an alicyclic epoxy compound (a) having two or more epoxy groups per molecule; a photocationic polymerization initiator (b); a silane coupling agent (c); and a thermal amine generator (f), in which the inkjet coating-type wiring protection composition has chloride ion content of 50 ppm or less, the inkjet coating-type wiring protection composition has a viscosity of 5 to 50 mPa·s measured at 25° C. and 20 rpm by using an E-type viscometer, and the thermal amine generator (f) is an adduct from an amine represented by the following general formula and an isocyanate

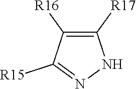

where R15, R16, and R17 independently represent a hydrogen atom, an alkyl group, or a phenyl group.

[8] The inkjet coating-type wiring protection composition according to [7], in which: the inkjet coating-type wiring protection composition has a surface tension of 20 to 40 mN/m.
[9] The inkjet coating-type wiring protection composition according to [7] or [8], in which: the alicyclic epoxy compound (a) has a cycloalkene oxide structure represented by the following general formula

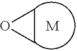

where which M represents an alicyclic structure having 4 to 8 carbon atoms.

[10] The inkjet coating-type wiring protection composition according to any one of [7] to [9], in which: based on 100 parts by mass of the alicyclic epoxy compound (a), the photocationic polymerization initiator (b) is contained in an amount of 0.1 to 10 parts by mass; the silane coupling agent (c) is contained in an amount of 1 to 50 parts by mass; and the thermal amine generator (f) is contained in an amount of 0.05 to 5 parts by mass.

The present invention provides a cured product and a semiconductor device as follows.

[11] A cured product of the inkjet coating-type wiring protection composition according to any one of [7] to [10], in which: the cured product has a loss tangent (tan δ) of 0.01 or more in a temperature range of 25° C. to 150° C. when dynamic viscoelasticity measurement is performed at a frequency of 1.6 Hz.
[12] A semiconductor device, including: a semiconductor circuit board or a board including metal wiring, the semiconductor circuit board including a circuit on at least one surface thereof; and a cured product layer that covers the semiconductor circuit board or the metal wiring of the board, in which the cured product layer contains a polymer and a silane coupling agent, the polymer being a polymer of an alicyclic epoxy compound having two or more epoxy groups per molecule, and the cured product layer has chloride ion content of 50 ppm or less.

The present invention also provides a method for producing a semiconductor device as follows.

[13] A method for producing a semiconductor device, the method including: preparing a semiconductor circuit board or a board including metal wiring, the semiconductor circuit board including a circuit on at least one surface thereof, applying the inkjet coating-type wiring protection composition according to any one of [7] to [10] on the circuit of the semiconductor circuit board or on the metal wiring of the board by an inkjet method; photo curing of curing a coating film of the inkjet coating-type wiring protection composition by irradiating the coating film with active light within 60 seconds after the applying; and thermal curing of curing the coating film after the photo curing with heat.

### Advantageous Effects of Invention

An inkjet coating-type wiring protection composition of the present invention can form a cured product having excellent pattern retention at high temperatures, and suitable adhesion to a circuit or the like for a long period of time. The cured product of the composition suffer less ion migration. The inkjet coating-type wiring protection composition can be applied by inkjet, thereby efficiently forming a cured product having a desired shape.

### DESCRIPTION OF EMBODIMENTS

1. Inkjet Coating-Type Wiring Protection Composition

An inkjet coating-type wiring protection composition (hereinafter also referred to simply as a “composition”) of the present invention is a composition to be applied by an inkjet method to form a layer for protection or insulation of, for example, a circuit and metal wiring of a semiconductor device. The composition of the present invention includes, but is not limited to, the following two aspects.

1. First Aspect

Polyimide resins have been mainly used for the protective layer or insulating layer of a semiconductor device or the like. However, it is difficult to form a layer including a polyimide resin directly into a pattern, and patterning is commonly performed by, for example, photolithography or etching. Alternatively, an epoxy resin or the like may be used to form a layer in a pattern. However, the composition containing a common epoxy resin has a high viscosity, and thus is difficult to be applied in a pattern. Further, a raw material containing chlorine is usually used in a production process of an epoxy resin, and thus chlorine ions are more likely to remain in the resin. Chloride ions may be mixed into the composition from the outside during the storage of the composition or when a semiconductor device or the like is produced by using the composition. The present inventors have found that when such a resin is used for, for example, a wiring protection layer or an insulating layer of a semiconductor device, chlorine ions migrate over time, which may cause corrosion of metal wiring or the like. It has also been found that presence of water between the protection layer or insulating layer and the metal wiring or the like is more likely to cause migration of, in particular, chloride ions.

Regarding the above findings, the composition of the first aspect contains a photocationically polymerizable compound (A), a photocationic polymerization initiator (B), and a silane coupling agent (C). The amount of the silane coupling agent (C) is 1 to 50 parts by mass based on 100 parts by mass of the photocationically polymerizable compound (A). The composition has a viscosity of 5 to 50 mPa·s measured at 25° C. and 20 rpm by using an E-type viscometer. In the composition of this aspect, the amount of the silane coupling agent (C) is relatively large with respect to the amount of the photocationically polymerizable compound (A). Therefore, the adhesion between the obtained cured film and a semiconductor circuit board, a board on which the metal wiring is disposed, or the like is greatly improved, and water hardly enters between the film and the board. The cured film is thus less likely to cause ion migration when used, for example, as a protective layer or an insulating layer of a semiconductor device, and is less likely to affect the circuit or metal wiring of the semiconductor device. In addition, the composition has a viscosity sufficiently low for application by an inkjet method to be formed into a film in a desired pattern.

The composition also contains a photocationic polymerization initiator (B), thus can be quickly cured by light and can maintain a desired shape. Therefore, the composition is very useful for forming a protective layer or an insulating layer that can sufficiently protect the circuit and metal wiring of a semiconductor device for a long period of time. Hereinafter, the composition of the present aspect will be described in detail.

Photocationically Polymerizable Compound (A)

The photocationically polymerizable compound (A) contains at least an alicyclic epoxy compound having two or more epoxy groups per molecule. The photocationically polymerizable compound (A) may contain, for example, an oxetane compound, an aliphatic epoxy compound, and an aromatic epoxy compound in addition to the alicyclic epoxy compound.

The alicyclic epoxy compound, which has two or more epoxy groups and at least one alicyclic structure per molecule, is preferably a compound that is liquid at room temperature. The number of epoxy groups per molecule in the alicyclic epoxy compound is at least two, and preferably two to four.

Examples of the alicyclic epoxy compound include compounds having a cycloalkene oxide structure represented by the general formula below. A cycloalkene oxide structure is obtained by epoxidizing a cycloalkene with an oxidizing agent such as a peroxide. The structure has an aliphatic ring and an epoxy group composed of an oxygen atom and two carbon atoms that are part of the aliphatic ring.

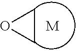

In the above general formula, M represents an alicyclic structure, and the number of carbon atoms of the alicyclic structure is preferably 4 to 8, more preferably 5 to 6. When the number of carbon atoms in the alicyclic structure of the cycloalkene oxide structure is in the above ranges, the viscosity of the composition is more likely to become low.

In general, the use of a compound that contains chlorine is not necessary for synthesizing an alicyclic epoxy compound having a cycloalkene oxide structure. Such an alicyclic epoxy compound is thus less likely to contain chlorine ions as compared to the other epoxy compounds.

Specific examples of the cycloalkene oxide structure include cyclohexene oxide, which is an preferred example, and cyclopentene oxide.

The number of cycloalkene oxide structures in one molecule of the alicyclic epoxy compound may be one (monofunctional) or two or more (polyfunctional). In particular, the number of cycloalkene oxide structures in one molecule of the alicyclic epoxy compound is preferably two or more (polyfunctional) from the viewpoint that the oxygen atom content described below can be readily increased and an excellent heat resistance can also be provided.

Example of the alicyclic epoxy compound having a cycloalkene oxide structure includes compounds represented by the below general formulas (A-1) to (A-3).

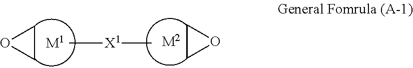

M¹ and M² in the general formula (A-1) each represent an alicyclic structure, and as described above, the number of carbon atoms of the alicyclic structure is preferably 4 to 8, more preferably 5 to 6. X¹ in the general formula (A-1) is a single bond or a linking group. The linking group is selected in such a way that the weight average molecular weight and the oxygen atom content of a compound represented by the formula (A-1) fall within the ranges described below. Examples of the linking group include divalent hydrocarbon group, carbonyl group, ether group (ether bond), thioether group (thioether bond), ester group (ester bond), carbonate group (carbonate bond), amide group (amide bond), and groups each having a plurality of these groups linked to each other.

Examples of the divalent hydrocarbon group include alkylene groups having 1 to 18 carbon atoms and divalent alicyclic hydrocarbon groups. Examples of the alkylene groups having 1 to 18 carbon atoms include methylene group, methylmethylene group, dimethylmethylene group, ethylene group, propylene group, and trimethylene group. Examples of the divalent alicyclic hydrocarbon groups include divalent cycloalkylene groups (including cycloalkylidene groups), such as 1,2-cyclopentylene group, 1,3-cyclopentylene group, cyclopentylidene group, 1,2-cyclohexylene group, 1,3-cyclohexylene group, 1,4-cyclohexylene group, and cyclohexylidene group.

In particular, X¹ is preferably a single bond or a linking group having at least one oxygen atom. More preferable linking groups having an oxygen atom are —CO— (carbonyl group), —O—CO—O— (carbonate group), —COO— (ester group), —O— (ether group), —CONH— (amide group), groups each having a plurality of these groups linked to each other, or groups each having one or more of these groups linked to one or more of divalent hydrocarbon groups.

Specific examples of the alicyclic epoxy compound represented by the general formula (A-1) include the compounds in the following paragraph. In the following formulas, 1 is an integer of 1 to 10, m is an integer of 1 to 30, R is an alkylene group having 1 to 8 carbon atoms (preferably an alkylene group having 1 to 3 carbon atoms, such as methylene group, ethylene group, propylene group and isopropylene group), and n1 and n2 are each an integer of 1 to 30.

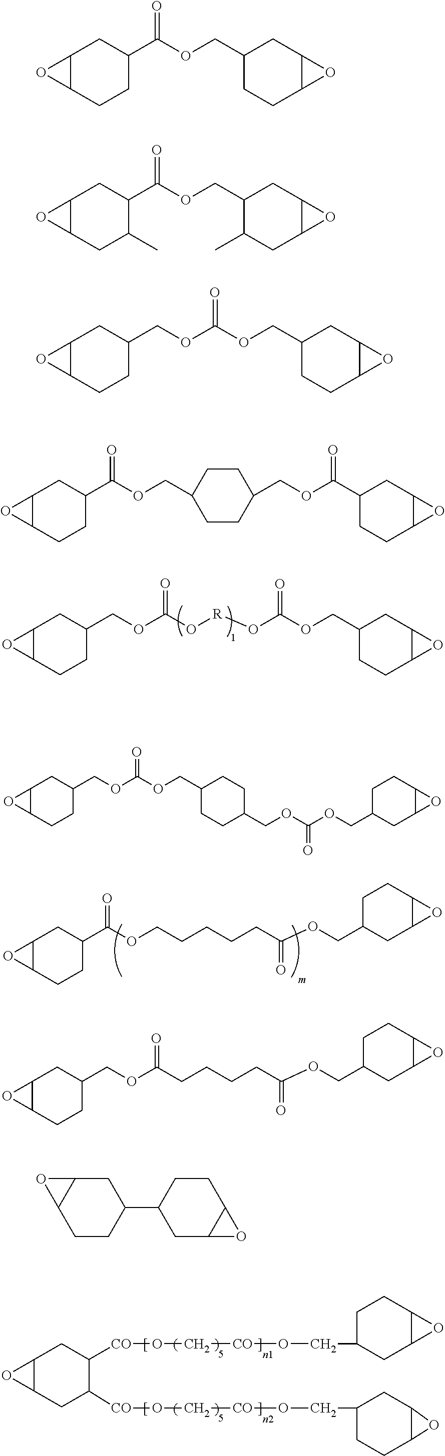

Examples of commercially available alicyclic epoxy compounds (A) represented by the general formula (A-1) include Celloxide 2021P, Celloxide 2081, Celloxide 8000, and Celloxide 8010 (all manufactured by Daicel Corporation).

The alicyclic epoxy compound (A) having a cycloalkene oxide structure may be, for example, a compound having a structure represented by the following general formula (A-2) or (A-3).

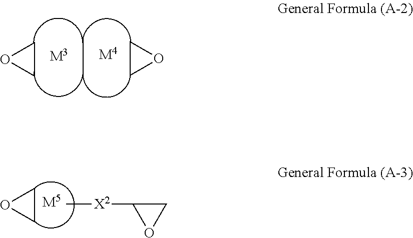

M³, M⁴, and M⁵ in the general formulas (A-2) and (A-3) each represent an alicyclic structure, and the number of carbon atoms of the alicyclic structure is preferably 4 to 8, more preferably 5 to 6. X² in the general formula (A-3) is a single bond or a linking group. The linking group is selected in such a way that the weight average molecular weight and the oxygen atom content of a compound represented by the formula (A-3) fall within the ranges described below. The linking group is the same as the linking group in the general formula (A-1). The compounds represented by the general formulas (A-2) and (A-3) may have an alkyl group or the like bonded to carbon of the alicyclic structure or of the epoxy group.

Examples of the alicyclic epoxy compound (A) represented by the general formula (A-2) or (A-3) include 3,4:7,8-diepoxybicyclo[4.3.0]nonane and limonene dioxide. Examples of commercially available products of the alicyclic epoxy compound (A) include THI-DE (manufactured by JX-TG) and LDO (manufactured by Nagase ChemteX Corporation).

For any of the above described alicyclic epoxy compounds, the weight average molecular weight thereof is preferably 180 or more, more preferably 190 or more, and even more preferably 200 or more. The upper limit of the weight average molecular weight is appropriately selected according to the viscosity of the composition, but is preferably 400 or less. A weight average molecular weight of the alicyclic epoxy compound of 180 or more can minimize volatilization of the alicyclic epoxy compound from the composition. As a result, during the application of the composition by the inkjet method, the component amount in the composition is less likely to change, and the working environment is less likely to be impaired. The weight average molecular weight of the alicyclic epoxy compound can be measured in terms of polystyrene by gel permeation chromatography (GPC).

The oxygen atom content (represented by the equation (1) below) of the alicyclic epoxy compound is preferably 15% or more, more preferably 20% or more. On the other hand, the oxygen atom content is preferably 30% or less.

Oxygen atom content(%)=Total mass of oxygen atoms in one molecule/Weight average molecular weight×100 Equation (1)

When the oxygen atom content of the alicyclic epoxy compound is 15% or more, the polarity of the alicyclic epoxy compound increases, lowering the affinity of the compound with an adhesive and a rubber material (such as ethylene propylene butadiene rubber) which have a low polarity and are used in the head portion of the inkjet device. As a result, the adhesive and rubber material are less likely to swell, and their degradation (damage to the device) is less likely to occur.

The total mass of oxygen atoms in one molecule of the alicyclic epoxy compound can be calculated as follows: specifying the structure of the alicyclic epoxy compound by GC-MS, NMR, or the like; specifying the number of oxygen atoms in one molecule of the compound; and then multiplying the number by the atomic weight of an oxygen atom. The oxygen atom content of the alicyclic epoxy compound can be calculated by applying the obtained total mass of oxygen atoms and the weight average molecular weight of the alicyclic epoxy compound measured by the GPC method to the above equation (1). The oxygen atom content of the alicyclic epoxy compound can be adjusted by the number of epoxy groups per molecule and the number of groups having oxygen atoms.

The oxetane compound has one or more oxetane groups per molecule, and preferably is a compound that is liquid at room temperature. In addition, the oxetane compound has a viscosity of preferably 1 to 500 mPa·s, more preferably 1 to 300 mPa·s, measured at 25° C. and 20 rpm by using an E-type viscometer. An oxetane compound having a viscosity in the above ranges is more likely to allow the viscosity of the composition to fall within a desired range and allow for stable application of the composition by the inkjet method.

An oxetane compound having a weight average molecular weight of 180 or more is less likely to volatilize in the inkjet device, thereby allowing stable application. The weight average molecular weight of the oxetane compound is preferably 190 or more, more preferably 200 or more, from the viewpoint of minimizing the volatilization of the oxetane compound. The upper limit of the weight average molecular weight may be any value as long as the ejection property of the composition is suitable for the application of the compound by the inkjet method, and is preferably 400 or less. The weight average molecular weight of the oxetane compound can be measured in the same manner as in the alicyclic epoxy compound.

The oxygen atom content of the oxetane compound is preferably 15% or more, more preferably 20% or more. On the other hand, the oxygen atom content of the oxetane compound is preferably 30% or less. When the oxygen atom content is high, the polarity of the oxetane compound increases, lowering the affinity of the compound with an adhesive and a rubber material (such as ethylene propylene butadiene rubber) which have a low polarity and are used in the head portion of the inkjet device. As a result, the adhesive and rubber material are less likely to swell, and their degradation (damage to the device) is less likely to occur. The oxygen atom content of the oxetane compound is defined in the same manner as in the alicyclic epoxy compound, and also the method for measuring the oxygen atom content can be the same as in the alicyclic epoxy compound.

The oxygen atom content of the oxetane compound can be adjusted by, for example, the number of oxetanyl groups per molecule of the oxetane compound, or the number of oxygen atoms in a group(s) bonded to the oxetanyl group.

The oxetane compound is preferably a compound represented by the general formula (B-1) or (B-2) below. The composition may contain only one type of oxetane compound, or two or more types of oxetane compound.

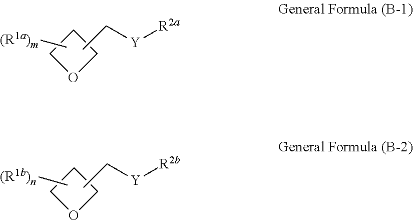

In the general formulas (B-1) and (B-2), Y represents an oxygen atom, a sulfur atom, or a single bond. In particular, an oxygen atom is preferred.

R^{1a} and R^{1b} each represent a fluorine atom, an alkyl group having 1 to 6 carbon atoms, a fluoroalkyl group having 1 to 6 carbon atoms, an allyl group, an aryl group having 6 to 18 carbon atoms, a furyl group, or a thienyl group. Each of m and n represents an integer of 1 or more and 5 or less. When a plurality of R^{1a}'s or R^{1b}'s are contained in one molecule, they may be the same or different. Further, adjacent R^{1a}'s or adjacent R^{1b}'s may form a ring structure.

R^{2a} in the general formula (B-1) represents a hydrogen atom, an alkyl group having 1 to 10 carbon atoms, an alkenyl group having 2 to 6 carbon atoms, an aralkyl group having 7 to 18 carbon atoms, an alkylcarbonyl group having 2 to 6 carbon atoms, an alkoxycarbonyl group having 2 to 6 carbon atoms, an N-alkylcarbamoyl group having 2 to 6 carbon atoms, or a (meth)acryloyl group.

R^{2b} in the general formula (B-2) represents a p-valent linking group, where p represents 2, 3, or 4. R^{2b} represents, for example, a linear or branched alkylene group having 1 to 12 carbon atoms, a linear or branched poly(alkyleneoxy) group, an arylene group, a siloxane bond, or a combination thereof.

R^{1a}, R^{1b}, R^{2a}, and R^{2b} in the general formulas (B-1) and (B-2) are preferably selected in such a way that the weight average molecular weight and the oxygen atom content fall within the above ranges.

In particular, the oxetane compound represented by the following general formula (B-3) or (B-4) is preferred from the viewpoint of obtaining an appropriate viscosity of the composition.

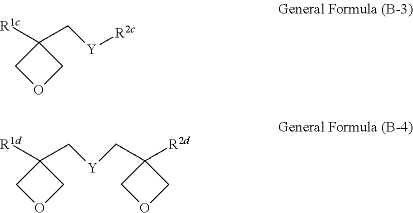

Y in the general formula (B-3) or (B-4) is an oxygen atom or a sulfur atom. R^{1c}, R^{1d}, and R^{2d} each represent a hydrogen atom, a fluorine atom, an alkyl group having 1 to 6 carbon atoms, a fluoroalkyl group having 1 to 6 carbon atoms, an aryl group having 6 to 18 carbon atoms, a furyl group or a thienyl group. In particular, an alkyl group having 1 to 6 carbon atoms is preferred from the viewpoint of reducing the viscosity of the composition.

R^{2c} is a hydrogen atom, an alkyl group having 1 to 10 carbon atoms, an alkenyl group having 2 to 6 carbon atoms, an aralkyl group having 7 to 18 carbon atoms, an alkylcarbonyl group having 2 to 6 carbon atoms, an alkoxycarbonyl group having 2 to 6 carbon atoms, an N-alkylcarbamoyl group having 2 to 6 carbon atoms, or a (meth)acryloyl group. In particular, an alkyl group having 1 to 10 carbon atoms is more preferred from the viewpoint of, for example, reducing the viscosity of the composition.

Examples of the compound represented by the general formula (B-3) include 3-ethyl-3-hydroxymethyloxetane, 3-(meth)allyloxymethyl-3-ethyloxetane, (3-ethyl-3-oxetanylmethoxy)methylbenzene, 4-fluoro-[1-(3-ethyl-3-oxetanylmethoxy)methyl]benzene, 4-methoxy-[1-(3-ethyl-3-oxetanylmethoxy)methyl]benzene, [1-(3-ethyl-3-oxetanylmethoxy)ethyl]phenylether, isobutoxymethyl(3-ethyl-3-oxetanylmethyl)ether, isobornyloxyethyl(3-ethyl-3-oxetanylmethyl)ether, isobornyl(3-ethyl-3-oxetanylmethyl)ether, 2-ethylhexyl(3-ethyl-3-oxetanylmethyl)ether, ethyldiethyleneglycol(3-ethyl-3-oxetanylmethyl)ether, dicyclopentadiene(3-ethyl-3-oxetanylmethyl)ether, 3-methyloxymethyl-3-ethyloxetane, and 3-ethyl-3-[(2-ethylhexyloxy)methyl]oxetane. In particular, 3-ethyl-3-[(2-ethylhexyloxy)methyl]oxetane is preferred. Examples of the compound represented by the general formula (B-4) include 3-ethyl-3{[(3-ethyloxetane-3-yl)methoxy]methyl}oxetane.

Examples of commercially available oxetane compounds include OXT-221, OXT-121, and OXT-212 (all manufactured by Toagosei Co., Ltd.), OXBP and HBOX (both manufactured by Ube Industries, Ltd.).

Each of the aliphatic epoxy compound and the aromatic epoxy compound preferably has two or more epoxy groups per molecule, and preferably is a compound that is liquid at room temperature. The weight average molecular weight of each of the aliphatic epoxy compound and the aromatic epoxy compound is preferably 180 or more, more preferably 190 or more, and even more preferably 200 or more. An aliphatic epoxy compound or an aromatic epoxy compound having a weight average molecular weight within the above ranges is less likely to volatilize in the inkjet device, thereby allowing stable application. The upper limit of the weight average molecular weight of the epoxy compound may be any value as long as the ejection property is not impaired during the application of the composition by the inkjet method, and is preferably 400 or less. The weight average molecular weight of the epoxy compound can be measured in the same manner as in the alicyclic epoxy compound.

The oxygen atom content of each of the aliphatic epoxy compound and the aromatic epoxy compound is preferably 15% or more, more preferably 20% or more. On the other hand, the oxygen atom content is preferably 30% or less. An oxygen atom content of the aliphatic epoxy compound or the aromatic epoxy compound in the above ranges lowers the affinity of the compound with an adhesive and a rubber material (such as ethylene propylene butadiene rubber) which have a low polarity and are used in the head portion of the inkjet device. The oxygen atom content of the aliphatic epoxy compound and the aromatic epoxy compound is defined in the same manner as in the alicyclic epoxy compound, and also the method for measuring the oxygen atom content can be the same as in the alicyclic epoxy compound.

A known compound can be used as the aliphatic epoxy compound or the aromatic epoxy compound, and the epoxy compound may have any structure. Examples of the aliphatic epoxy compound include known compounds such as neopentyl glycol glycidyl ether. Examples of aromatic epoxy compounds also include known compounds.

The amount of the photocationically polymerizable compound (A) is preferably 10 to 99 mass %, more preferably 15 to 98 mass %, and even more preferably 15 to 97 mass %, based on the total solid content of the composition. When the amount of the photocationically polymerizable compound (A) is in the above ranges, the strength of the obtained film is increased, and further, the film shrinkage is less likely to occur during curing of the composition or after the composition is cured.

The amount of the alicyclic epoxy compound contained in the photocationically polymerizable compound (A) is preferably 1 to 100 parts by mass, more preferably 5 to 100 parts by mass, and even more preferably 50 to 100 parts by mass, based on 100 parts by mass of the total amount of the photocationically polymerizable compound (A). When the amount of the alicyclic compound is in the above ranges, chloride ions and the like are less likely to be generated, thereby increasing the ion migration resistance of a cured product.

The amount of the oxetane compound contained in the photocationically polymerizable compound (A) is preferably 0 to 50 parts by mass, more preferably 0 to 40 parts by mass, and even more preferably 0 to 30 parts by mass, based on 100 parts by mass of the total amount of the photocationically polymerizable compound (A). When the photocationically polymerizable compound (A) contains the oxetane compound in an amount of the above ranges, the viscosity of the composition is more likely to fall within a desired range. When the amount of oxetane compound is 50 parts by mass or less, the amount the alicyclic epoxy compound relatively increases, and thus the strength of the cured product of the composition is more likely to increase.

The total amount of the aliphatic epoxy compound and the aromatic epoxy compound contained in the photocationically polymerizable compound (A) is preferably 0 to 50 parts by mass, more preferably 0 to 40 parts by mass, and even more preferably 0 to 30 parts by mass, based on 100 parts by mass of the total amount of the photocationically polymerizable compound (A). When the total amount of the aliphatic epoxy compound and the aromatic epoxy compound is within the above ranges, shrinkage or the like is less likely to occur during curing of the composition.

Photocationic Polymerization Initiator (B)

The photocationic polymerization initiator (B) may be any compound that generates active species capable of initiating cationic polymerization by irradiation with an active light such as ultraviolet light. The amount of the photocationic polymerization initiator (B) contained in the composition is preferably 0.1 to 10 parts by mass, more preferably 0.1 to 5 parts by mass, based on 100 parts by mass of the photocationically polymerizable compound (A).

Examples of the photocationic polymerization initiator (B) include aromatic sulfonium salts, aromatic iodonium salts, aromatic diazonium salts, and aromatic ammonium salts. The anion moiety of the salts is preferably BF₄—, PX₆— (X is a fluorine atom or a fluoroalkyl group), SbF₆—, or BX₄— (X is a phenyl group substituted with at least two fluorine atoms or a trifluoromethyl group). The composition may contain only one type of photocationic polymerization initiator (B), or two or more types of photocationic polymerization initiator (B).

Examples of the aromatic sulfonium salts include bis[4-(diphenylsulfonio)phenyl]sulfide bis(hexafluorophosphate), bis[4-(diphenylsulfonio)phenyl]sulfide bis(hexafluoroantimonate), bis[4-(diphenylsulfonio)phenyl]sulfide bis(tetrafluoroborate), bis[4-(diphenylsulfonio)phenyl]sulfide tetrakis(pentafluorophenyl)borate, diphenyl-4-(phenylthio)phenylsulfonium hexafluorophosphate, diphenyl-4-(phenylthio)phenylsulfonium hexafluoroantimonate, and diphenyl-4-(phenylthio)phenylsulfonium tetrafluoroborate.

Examples of the aromatic iodonium salts include diphenyliodonium hexafluorophosphate, diphenyliodonium hexafluoroantimonate, diphenyliodonium tetrafluoroborate, diphenyliodonium tetrakis(pentafluorophenyl)borate, bis(dodecylphenyl)iodonium hexafluorophosphate, bis(dodecylphenyl)iodonium hexafluoroantimonate, bis(dodecylphenyl)iodonium tetrafluoroborate, and bis(dodecylphenyl)iodonium tetrakis(pentafluorophenyl)borate.

Examples of the aromatic diazonium salts include phenyldiazonium hexafluorophosphate, phenyldiazonium hexafluoroantimonate, phenyldiazonium tetrafluoroborate, and phenyldiazonium tetrakis(pentafluorophenyl)borate.

Examples of the aromatic ammonium salts include 1-benzyl-2-cyanopyridinium hexafluorophosphate and 1-benzyl-2-cyanopyridinium hexafluoroantimonate.

Examples of commercially available photocationic polymerization initiators (B) include Irgacure 250, Irgacure 270, and Irgacure 290 (manufactured by BASF), CPI-100P, CPI-101A, CPI-200K, CPI-210S, CPI-310B, CPI-310FG, and CPI-400PG (manufactured by San-Apro Ltd.), and SP-150, SP-170, SP-171, SP-056, SP-066, SP-130, SP-140, SP-601, SP-606, and SP-701 (manufactured by ADEKA CORPORATION). In particular, sulfonium salts such as Irgacure 270, Irgacure 290, CPI-100P, CPI-101A, CPI-200K, CPI-210S, CPI-310B, CPI-310FG, CPI-400PG, SP-150, SP-170, SP-171, SP-056, SP-066, SP-601, SP-606, and SP-701 are preferred.

Silane Coupling Agent (C)

The silane coupling agent (C) is a compound having silane, and having a function of improving the adhesiveness of the cured product of the composition to the metal wiring or the board of a semiconductor device. In the composition of the present aspect, the silane coupling agent (C) minimizes the migration of chloride ions and the like in the cured product. The amount of the silane coupling agent (C) contained in the composition is preferably 1 to 50 parts by mass, more preferably 4 to 45 parts by mass, based on 100 parts by mass of the photocationically polymerizable compound (A). A silane coupling agent in an amount of 1 part by mass or more can sufficiently minimize migration of chloride ions and the like in the cured product. On the other hand, when the amount of the silane coupling agent (C) is 50 parts by mass or less, the amount of the photocationically polymerizable compound (A) relatively increases, and the cured product is less likely to shrink.

Examples of the silane coupling agent (C) include silane compounds having a reactive group such as an epoxy group, a carboxyl group, a methacryloyl group, and an isocyanate group. More specific examples of the silane coupling agent (C) include trimethoxysilyl benzoate, γ-methacryloxypropyltrimethoxysilane, vinyltriacetoxysilane, vinyltrimethoxysilane, γ-isocyanatopropyltriethoxysilane, γ-glycidoxypropyltrimethoxysilane, and β-(3,4-epoxycyclohexyl)ethyltrimethoxysilane. The composition may contain only one type of silane compound (C), or two or more types of silane compound (C).

The silane coupling agent (C) may include a relatively high molecular weight compound (hereinafter referred to as a “high molecular weight silane coupling agent”). The high molecular weight silane coupling agent has a Si—O—Si skeleton, an alkoxy group, and an epoxy group in one molecule thereof, and has a weight average molecular weight of 1,000 or more. The weight average molecular weight of the high molecular weight silane coupling agent is preferably 1,000 to 5,000, more preferably 1,500 to 2,500. When the silane coupling agent (C) has a siloxane skeleton (Si—O—Si skeleton) and has a weight average molecular weight of 1,000 or more, the silane coupling agent (C) is more likely to be unevenly distributed on the surface of the metal wiring and the like of a semiconductor device. As a result, the adhesion of the cured product of the composition to the metal wiring and the like of the semiconductor device is more likely to improve even in a high temperature and high humidity environment. A silane coupling agent (C) having an epoxy group is more likely to form a network with the photocationically polymerizable compound (A), in particular, the alicyclic epoxy compound and the like, and less likely to emerge from the cured product. A silane coupling agent (C) having a weight average molecular weight of 5,000 or less meanwhile is more likely to allow the viscosity of the composition to fall within a desired range. The weight average molecular weight of the silane coupling agent (C) can be measured in terms of polystyrene by gel permeation chromatography (GPC).

The high molecular weight silane coupling agent may be any compound that has a siloxane skeleton (Si—O—Si skeleton), an alkoxy group bonded to Si of the siloxane skeleton, and an epoxy group, and has a molecular weight within the above ranges. Such a high molecular weight silane coupling agent can be obtained by polymerizing, for example, dialkoxysilane, trialkoxysilane, or tetraalkoxysilane. During the polymerization, using a monomer having an epoxy group in a part thereof or allowing epichlorohydrin to react can introduce the epoxy group into the molecule. The siloxane skeleton (Si—O—Si skeleton) may be a skeleton in which Si and O are linearly linked, or a skeleton in which Si and O are linked in a three-dimensional network.

The silane coupling agent has at least one alkoxy group bonded to each siloxane skeleton, but preferably has a plurality of alkoxy groups per molecule from the viewpoint of improving the adhesion between the cured product obtained from the composition and a semiconductor circuit or the like. The number of the epoxy groups is preferably two or more. In addition to the alkoxy group and the epoxy group, another group may be bonded to the siloxane skeleton. Examples of the additional group bonded to the siloxane skeleton include (meth)acryloyl group, phenyl group, mercapto group, and oxetanyl group.

The high molecular weight silane coupling agent may be prepared by polymerizing at least one of various alkoxysilanes, or may be a commercially available product. Examples of the commercially available product include KR-500, KR-510, KR-516, KR-517, X-40-2670, X-12-981S, and X-12-984S (all manufactured by Shin-Etsu Chemical Co., Ltd.).

Additional Components (D)

The composition may additionally contain one or more components other than the photocationically polymerizable compound (A), photocationic polymerization initiator (B), and silane coupling agent (C) as long as the effects of the present aspect are not impaired. Examples of the additional components include thermalcationic polymerization initiators, sensitizers, and leveling agents.

The thermalcationic polymerization initiator may be any compound that generates active species capable of initiating cationic polymerization by heating. Examples of the thermalcationic polymerization initiator include known cationic polymerization initiators. Examples of the thermal cationic polymerization initiator include sulfonium salts, phosphonium salts, quaternary ammonium salts, diazonium salts, and iodonium salts. In particular, quaternary ammonium salts and sulfonium salts are preferred. The anion moiety of the salts is preferably, for example, AsF₆⁻, SbF₆⁻, PF₆⁻, or B(C₆F₅)⁴⁻. The composition may contain only one type of thermalcationic polymerization initiator or two or more types of thermalcationic polymerization initiator.

The amount of the thermalcationic polymerization initiator is preferably 10% by mass or less, more preferably 5% by mass or less, based on the total amount of the composition.

The sensitizer is a compound having a function of further improving the efficiency of generating active species of the photocationic polymerization initiator (B) or the thermalcationic polymerization initiator to further promote the curing reaction of the composition. Examples of the sensitizer include thioxanthone compounds such as 2,4-diethylthioxanthon; benzophenone compounds such as 2,2-dimethoxy-1,2-diphenylethane-1-one, benzophenone, 2,4-dichlorobenzophenone, o-methyl benzoyl benzoate, 4,4′-bis(dimethylamino)benzophenone, and 4-benzoyl-4′-methyldiphenylsulfide; and anthracene compounds such as 9,10-diethoxyanthracene, 9,10-dibutoxyanthracene, and 9,10-bis(octanoyloxy)anthracene.

The leveling agent is a compound for improving the flatness of the coating film of the composition. Examples of the leveling agent include silicone-based, acrylic-based, and fluorine-based compounds. Examples of commercially available leveling agents include BYK-340 and BYK-345 (both manufactured by BYK Japan KK), and SURFLON S-611 (manufactured by AGC SEIMI CHEMICAL CO., LTD.).

The total content of the sensitizer and the leveling agent is preferably 20% by mass or less, more preferably 10% by mass or less, based on the total amount of the composition, from the viewpoint of reducing the low molecular weight components and reducing the damage to the device.

Physical Properties of Composition

Viscosity

The viscosity of the composition of the present aspect measured by using an E-type viscometer at 25° C. and 20 rpm is 5 to 50 mPa·s, preferably 5 to 30 mPa·s, and more preferably 10 to 20 mPa s. A viscosity in the above ranges is more likely to improve the ejection property during the application of the composition by the inkjet method.

Chloride Ion Concentration

The chloride ion content of the composition of the present aspect is preferably 50 ppm or less, more preferably 30 ppm or less, and even more preferably 10 ppm or less. When the chloride ion concentration is 50 ppm or less, ion migration is less likely to occur over a long period of time in the semiconductor device that includes the cured product of the composition, thereby minimizing the corrosion of the semiconductor device. The concentration of the chloride ions in the composition can be determined as follows. The composition is collected in a pressure-resistant container made of polytetrafluoroethylene (PTFE) and weighed, then 10 mL of pure water is added, and the container was sealed tightly. Chlorine is then heat extracted in an oven at 100° C. (set temperature) for 20 hours. The extract is then allowed to cool to room temperature, and is recovered to perform quantitative analysis of chloride ions by an ion chromatograph method (IC method).

Surface Tension

The surface tension of the composition of the present aspect is preferably 20 to 40 mN/m, more preferably 25 to 40 mN/m, and even more preferably 25 to 35 mN/m. Surface tension is a value measured by the Wilhelmy method at 25° C. Surface tension of the composition of 40 mN/m or less allows easier leveling during the application of the composition by the inkjet method, and thus the composition can evenly coat, for example, the circuit of a semiconductor circuit board. On the other hand, when the surface tension of the composition is 20 mN/m or more, the composition is less likely to spread to wet the surface excessively during the application of the composition by the inkjet method, thereby maintaining the desired thickness and pattern.

Oxygen Content

The oxygen content of the composition is preferably 15% or more, more preferably 20% or more, from the viewpoint of reducing damage to the inkjet device. On the other hand, the oxygen atom content of the composition is preferably 30% or less. The oxygen atom content of the composition can be calculated from the following formula: (Total mass of oxygen atoms contained in the composition/Total mass of the composition)×100(%). The total mass of oxygen atoms contained in the composition can be calculated by calculating the proportion of oxygen atoms contained in the composition by element analysis and multiplying the proportion by the atomic weight of oxygen atoms.

Physical Properties of Cured Product

The loss tangent (tan δ) of the cured product of the composition at 25° C. to 150° C., obtained by dynamic viscoelasticity measurement at a frequency of 1.6 Hz (10 rad/s), is preferably 0.01 or more, more preferably 0.03 or more, and even more preferably 0.05 or more. The above values are determined by the measurement after irradiating the composition with light having a wavelength of 395 nm at 450 mJ/cm² and further curing the composition at 23° C. for 30 minutes. When the loss tangent (tan δ) of the cured product is within the above ranges, ion migration is less likely to occur.

The storage elastic modulus E′ of the cured product at 85° C., obtained by dynamic viscoelasticity measurement at a frequency of 1.6 Hz (10 rad/s), is preferably 1×10⁶ Pa to 1×10¹⁰ Pa, more preferably 1×10⁷ Pa to 1×10¹⁰ Pa. The loss tangent (tan δ) under this condition is preferably 0.03 or more, and more preferably 0.05 or more.

When a cured product whose storage elastic modulus and the loss tangent at 85° C. are within the above ranges is used for a repassivation layer or the like of a semiconductor device, the repassivation layer or the like is more likely to sufficiently absorb impact even in a high temperature environment.

In addition, the peak of the loss tangent (tan δ) of the cured product, obtained by dynamic viscoelasticity measurement at a frequency of 1.6 Hz (10 rad/s), is in the range of preferably 50° C. to 200° C., more preferably 100° C. to 200° C., and even more preferably 120 to 200° C. When the peak of the loss tangent is within the above ranges, ion migration is less likely to occur.

The viscosity of the above composition measured at 25° C. and 20 rpm by using an E-type viscometer after irradiating the composition with light having a wavelength of 395 nm at 23° C. and 450 mW/cm² is preferably 50 mPa·s or more, more preferably 70 mPa·s or more. When the viscosity after irradiation with light is within the above ranges, the shape of the composition is less likely to change after irradiation with light, allowing a desired shape to be maintained.

Method for Preparing Composition

The composition can be obtained by mixing the above components by using a mixer such as a homodisper, a homomixer, a universal mixer, a planetary mixer, a kneader, or a three roll mixer.

2. Second Aspect

Polyimide resins have been mainly used for the protective layer or insulating layer of a semiconductor device or the like. However, it is difficult to form a layer including a polyimide resin directly into a pattern, and patterning is commonly performed by, for example, photolithography or etching. Alternatively, an epoxy resin or the like may be used to form a layer in a pattern. However, the composition containing a common epoxy resin has a high viscosity, and thus is difficult to be applied in a pattern. Further, a raw material containing chlorine is usually used in a production process of an epoxy resin, and thus chlorine ions are more likely to remain in the resin. The present inventors have found that when such a resin is used for, for example, a wiring protection layer or an insulating layer of a semiconductor device, chlorine ions migrate over time, which may cause corrosion of metal wiring or the like.

Regarding the above findings, the composition of the present aspect contains an alicyclic epoxy compound (a), a photocationic polymerization initiator (b), a silane coupling agent (c), and a thermal amine generator (f). The composition has chloride ion content of 50 ppm or less, and a viscosity of 5 to 50 mPa·s measured at 25° C. and 20 rpm by using an E-type viscometer. The composition of the present aspect has extremely low chloride ion concentration, and thus is less likely to cause ion migration when the composition is used, for example, as a protective layer or an insulating layer of a semiconductor device. In addition, the composition has a viscosity sufficiently low for application by an inkjet method to be formed into a film in a desired pattern.

In addition, the composition of the present aspect contains a silane coupling agent (c), and thus the cured product thereof easily adheres to various metal wiring, boards, and the like even at high temperatures. The composition also contains a photocationic polymerization initiator (b), and thus can be quickly cured by light and can maintain a desired shape. The composition further contains a thermal amine generator having a specific structure (f), and thus the composition does not inhibit photocationic polymerization, while amine generated by thermal cleavage of amine and isocyanate adduct during thermal curing traps cations such as protons. This is considered to be the reason for the improved PCT resistance of the cured product. Therefore, the composition is very useful for forming a protective layer or an insulating layer that can sufficiently protect wiring of a semiconductor circuit and the like for a long period of time. Hereinafter, the composition of the present aspect will be described in detail.

Alicyclic Epoxy Compound (a)

The alicyclic epoxy compound (a) has, per molecule, two or more epoxy groups and at least one alicyclic structure. The alicyclic epoxy compound (a) is preferably a compound that is liquid at room temperature. The amount of the alicyclic epoxy compound (a) is preferably 30 to 99 parts by mass, more preferably 50 to 99 parts by mass, and even more preferably 80 to 99 parts by mass, based on 100 parts by mass of the total amount of the composition.

The composition may contain only one type of alicyclic epoxy compound (a), or two or more types of alicyclic epoxy compound (a). The number of epoxy groups per molecule in the alicyclic epoxy compound (a) is preferably at least two, and more preferably two to four.

The alicyclic epoxy compound (a) is the same as the compound having a cycloalkene oxide structure in the photocationically polymerizable compound (A) of the first aspect.

In general, the use of a compound that contains chlorine is not necessary for synthesizing an alicyclic epoxy compound (a) having a cycloalkene oxide structure as described above. The alicyclic epoxy compound (a) is thus less likely to contain chlorine ions, allowing the chlorine ion concentration in the composition to fall in the above range.

The weight average molecular weight of the aliphatic epoxy compound (a) in the present aspect is preferably 180 or more, more preferably 190 or more, and even more preferably 200 or more. The upper limit of the weight average molecular weight is appropriately selected according to the viscosity of the composition, but is preferably 400 or less. A weight average molecular weight of the alicyclic epoxy compound (a) of 180 or more can minimize volatilization of the alicyclic epoxy compound (a) from the composition. As a result, during the application of the composition by the inkjet method, the component amount in the composition is less likely to change, and the working environment is less likely to be impaired. The weight average molecular weight of the alicyclic epoxy compound can be measured in terms of polystyrene by gel permeation chromatography (GPC).

The oxygen atom content of the alicyclic epoxy compound (a) is preferably 15% or more, more preferably 20% or more. On the other hand, the oxygen atom content is preferably 30% or less. The oxygen atom content can be calculated by the method described above.

Also in the present aspect, when the oxygen atom content of the alicyclic epoxy compound (a) is 15% or more, the polarity of the alicyclic epoxy compound (a) increases, lowering the affinity of the compound with an adhesive and a rubber material (such as ethylene propylene butadiene rubber) which have a low polarity and are used in the head portion of the inkjet device. As a result, the adhesive and rubber material are less likely to swell, and their degradation (damage to the device) is less likely to occur.

Photocationic Polymerization Initiator (b)

The photocationic polymerization initiator (b) may be any compound that generates active species capable of initiating cationic polymerization by irradiation with an active light such as ultraviolet light. The amount of the photocationic polymerization initiator (b) contained in the composition is preferably 0.1 to 10 parts by mass, more preferably 0.1 to 5 parts by mass, based on 100 parts by mass of the alicyclic epoxy compound (a).

The photocationic polymerization initiator (b) is the same as the photocationic polymerization initiator (B) of the first aspect described above. The composition may contain only one type of photocationic polymerization initiator (b), or two or more types of photocationic polymerization initiator (b).

Silane Coupling Agent (c)

The silane coupling agent (c) is a compound having silane, and having a function of improving the adhesiveness of the cured product of the composition to the metal wiring or the board of a semiconductor device. The amount of the silane coupling agent (c) contained in the composition is preferably 1 to 50 parts by mass, more preferably 1 to 25 parts by mass, and even more preferably 1 to 20 parts by mass, based on 100 parts by mass of the alicyclic epoxy compound (a).

The silane coupling agent (c) is the same as the silane coupling agent (C) of the first aspect described above. The composition may contain only one type of silane compound (c), or two or more types of silane compound (c).

Also in the present aspect, the silane coupling agent (c) may include a relatively high molecular weight compound (hereinafter referred to as a “high molecular weight silane coupling agent”). The high molecular weight silane coupling agent has a Si—O—Si skeleton, an alkoxy group, and an epoxy group in one molecule thereof, and has a weight average molecular weight of 1,000 or more. The weight average molecular weight of the high molecular weight silane coupling agent is preferably 1,000 to 5,000, more preferably 1,500 to 2,500. When the silane coupling agent (c) has a siloxane skeleton (Si—O—Si skeleton) and has a weight average molecular weight of 1,000 or more, the silane coupling agent (c) is more likely to be unevenly distributed on the surface of the metal wiring and the like of a semiconductor device. As a result, the adhesion of the cured product of the composition to the metal wiring and the like of the semiconductor device is more likely to improve even in a high temperature and high humidity environment. A silane coupling agent (c) having an epoxy group is more likely to form a network with the alicyclic epoxy compound (a), and less likely to emerge from the cured product. A silane coupling agent having a weight average molecular weight of 5,000 or less meanwhile is more likely to allow the viscosity of the composition to fall within a desired range. The weight average molecular weight of the silane coupling agent (c) can be measured in terms of polystyrene by gel permeation chromatography (GPC).

The high molecular weight silane coupling agent is the same as the high molecular weight silane coupling agent of the first aspect described above.

Thermal Amine Generator (f)

The thermal amine generator (f) is a latent amine generator that generates amines by heat, and preferably a compound that is liquid at room temperature. The amount of the thermal amine generator (f) is preferably 0.05 to 5 parts by mass, more preferably 0.5 to 4.0 parts by mass, and even more preferably 1.0 to 3.0 parts by mass, based on 100 parts by mass of the total amount of the alicyclic epoxy compound (a).

The composition may contain only one type of thermal amine generator (f), or two or more types of thermal amine generator (f). It is preferable that the amine group to which isocyanate is not added is not contained from the viewpoint of maintaining the photocurability.

Examples of the thermal amine generator (f) include compounds having a structure in which isocyanate is added to an amine represented by the following general formula.

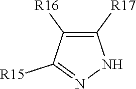

In the above general formula, R15, R16, and R17 independently represent a hydrogen atom, an alkyl group, or a phenyl group. R15, R16, and R17 may be the same group or different groups.

Examples of the amine represented by the above general formula include pyrazole, alkyl-substituted pyrazoles, and compounds whose hydrogen bonded to carbon in the above amines is substituted with an alkyl group.

The thermal amine generator (f) is preferably a compound obtained by reacting isocyanate and an amine having the above structure charged at an equivalent ratio (amine equivalent/isocyanate equivalent) of 1. This reaction is usually carried out at room temperature, but may be carried out at a temperature up to about 100° C. When the thermal amine generator (f) is heated to about 100° C. or higher, the amine is easily dissociated. A solvent may or may not be used for synthesizing the adduct. Examples of the solvent (if the solvent is used for the reaction) include aromatic solvents, hydrocarbon solvents, ketone solvents, amide solvents, sulfoxide solvents, ester solvents, alcohol solvents, and ether solvents.

The isocyanate for synthesizing the thermal amine generator (f) may be a monoisocyanate or a polyisocyanate having a plurality of isocyanate groups per molecule, but is more preferably a polyisocyanate. When a polyisocyanate is used as the isocyanate, the isocyanate group generated by the dissociation of the amine reacts with the hydroxyl group and the like in the other components of the composition. This isocyanate thus also functions as a cross-linking agent. The isocyanate may be either an aromatic isocyanate or an aliphatic isocyanate, but an aromatic isocyanate generally has a lower amine generation temperature in the thermal amine generator (f).

Examples of diisocyanates include tolylene diisocyanate (TDI), diphenylmethane diisocyanate (MDI), p-phenylene diisocyanate, xylylene diisocyanate (XDI), naphthalene diisocyanate (NDI), tolidine diisocyanate (TODI), hydrogenated diphenylmethane diisocyanate (H12MDI), hydrogenated xylylene diisocyanate (H6XDI), hydrogenated tolylene diisocyanate (H6TDI), trans cyclohexanes, 1,4-diisocyanate, hexamethylene diisocyanate (HDI), and isophorone diisocyanate (IPDI).

Examples of trifunctional or higher functional polyisocyanates include compounds derived from diisocyanates and triphenylmethane triisocyanate. Specific examples of the polyisocyanate derived from diisocyanate compounds include isocyanurate modified products, allophanate modified product, a biuret modified products, and urea modified products.

A polyol modified polyisocyanate obtained by modifying a polyisocyanate with a polyol may be used for the thermal amine generator (f). Such a compound can improve the solubility of the thermal amine generator (f), which includes isocyanate and amine, into the additional components. The polyol modification means that a polyol and a polyisocyanate charged at an equivalent ratio (isocyanate group equivalent/hydroxyl group equivalent) exceeding 1 are reacted to obtain a compound having isocyanate groups at both ends of the molecule thereof. This reaction is usually carried out at room temperature, but may be carried out at a temperature up to about 150° C. The urethanization catalyst may or may not be used, and the solvent may or may not be used.

Examples of the solvent that can be used for the reaction include aromatic solvents, hydrocarbon solvents, ketone solvents, amide solvents, sulfoxide solvents, ester solvents, alcohol solvents, and ether solvents. Herein, a polyol is a polyhydric alcohol compound that may be any one of the following: a low molecular weight diol and a high molecular weight diol each having two hydroxyl groups per molecule, a low molecular weight polyol and a high molecular weight polyol each having hydroxyl groups whose average number exceeding 2 per molecule. These polyols may be used alone or in combination.

A urea compound, such as the thermal amine generator (f), formed by the reaction of a specific amine with an isocyanate is considered to have a property such that the bond between the carbonyl carbon and the nitrogen atom on the amine side is easily broken due to steric hindrance or electronic reasons. Therefore, heating the compound to 100 to 150° C. easily regenerate the isocyanate, and the generated amine acts as a proton scavenger. The generated isocyanate reacts with the hydroxyl groups of the other components in the composition and is incorporated as a polymer. The urea compound is also considered to react with a chain extender to produce polyurethane and/or polyurea resin.

Additional Components

The composition of the present aspect may additionally contain one or more components other than the alicyclic epoxy compound (a), photocationic polymerization initiator (b), silane coupling agent (c), and the thermal amine generator (f) as long as the effects and objects of the present aspect are not impaired. Examples of the additional components include oxetane compounds, epoxy compounds other than the alicyclic epoxy compound (a), thermalcationic polymerization initiators, sensitizers, and leveling agents.

The oxetane compound preferably is a compound that has one or more oxetane groups per molecule, and is liquid at room temperature. In addition, the oxetane compound has a viscosity of preferably 1 to 500 mPa·s, more preferably 1 to 300 mPa·s, measured at 25° C. and 20 rpm by using an E-type viscometer. An oxetane compound having a viscosity in the above ranges is more likely to allow the viscosity of the composition to fall within the desired range and allow for stable application of the composition by the inkjet method.

An oxetane compound having a weight average molecular weight of 180 or more is less likely to volatilize in the inkjet device, thereby allowing stable application. The weight average molecular weight of the oxetane compound is preferably 190 or more, more preferably 200 or more, from the viewpoint of minimizing the volatilization of the oxetane compound. The upper limit of the weight average molecular weight may be any value as long as the ejection property is not impaired during the application of the composition by the inkjet method, and is preferably 400 or less. The weight average molecular weight of the oxetane compound can be measured in the same manner as in the alicyclic epoxy compound (a).

The oxygen atom content of the oxetane compound is preferably 15% or more, more preferably 20% or more. On the other hand, the oxygen atom content is preferably 30% or less. When the oxygen atom content is high, the polarity of the oxetane compound increases, lowering the affinity of the compound with an adhesive and a rubber material (such as ethylene propylene butadiene rubber) which have a low polarity and are used in the head portion of the inkjet device. As a result, the adhesive and rubber material are less likely to swell, and their degradation (damage to the device) is less likely to occur. The oxygen atom content of the oxetane compound is defined in the same manner as described above, and also the method for measuring the oxygen atom content can be the same as the method described above.

The oxygen atom content of the oxetane compound can be adjusted by, for example, the number of oxetanyl groups per molecule of the oxetane compound, or the number of oxygen atoms in a group bonded to the oxetanyl group.

The oxetane compound is the same as the oxetane compound contained in the photocationically polymerizable compound (A) of the first aspect described above. The composition may contain only one type of oxetane compound, or two or more types of oxetane compound.

The amount of the oxetane compound is preferably 40 parts by mass or less, more preferably 25 parts by mass or less, based on 100 parts by mass of the total amount of the composition. The presence of the oxetane compound is more likely to allow the viscosity of the composition to fall within a desired range. When the amount of oxetane compound is 40 parts by mass or less, the amount the alicyclic epoxy compound (a) relatively increases, and thus the strength of the cured product of the composition is more likely to increase.

Examples of the epoxy compounds other than the alicyclic epoxy compound (a) include aliphatic epoxy compounds and aromatic epoxy compounds. Each of the aliphatic epoxy compound and the aromatic epoxy compound preferably has two or more epoxy groups per molecule, and preferably is a compound that is liquid at room temperature. The weight average molecular weight of each of the aliphatic epoxy compound and the aromatic epoxy compound is preferably 180 or more, more preferably 190 or more, and even more preferably 200 or more. An aliphatic epoxy compound or an aromatic epoxy compound having a weight average molecular weight within the above ranges is less likely to volatilize in the inkjet device, thereby allowing stable application. The upper limit of the weight average molecular weight of the epoxy compound may be any value as long as the ejection property is not impaired during the application of the composition by the inkjet method, and is preferably 400 or less. The weight average molecular weight of the epoxy compound can be measured in the same manner as in the alicyclic epoxy compound (a).

The oxygen atom content of each of the aliphatic epoxy compound and the aromatic epoxy compound is preferably 15% or more, more preferably 20% or more. On the other hand, the oxygen atom content is preferably 30% or less. An oxygen atom content of the aliphatic epoxy compound or the aromatic epoxy compound in the above ranges lowers the affinity of the compound with an adhesive and a rubber material (such as ethylene propylene butadiene rubber) which have a low polarity and are used in the head portion of the inkjet device. The oxygen atom content of the aliphatic epoxy compound and the aromatic epoxy compound is defined in the same manner as in the alicyclic epoxy compound (a), and also the method for measuring the oxygen atom content can be the same as in the alicyclic epoxy compound.

A known compound can be used as the aliphatic epoxy compound or the aromatic epoxy compound, and the epoxy compound may have any structure. The amount of the aliphatic epoxy compound and the aromatic epoxy compound is preferably small from the viewpoint of reducing the chloride ion content in the composition, and is preferably 20 parts by mass or less, more preferably 10 parts by mass or less, based on 100 parts by mass of the total amount of the composition.

The thermalcationic polymerization initiator may be any compound that generates active species capable of initiating cationic polymerization by heating. Examples of the thermalcationic polymerization initiator include known cationic polymerization initiators. The thermalcationic polymerization initiator is the same as the thermalcationic polymerization initiator in the first aspect.

The sensitizer is a compound having a function of further improving the efficiency of generating active species of the photocationic polymerization initiator (b) or the thermalcationic polymerization initiator to further promote the curing reaction of the composition. Examples of the sensitizer are the same as those of the sensitizer in the first aspect.

The leveling agent is a compound for improving the flatness of the coating film of the composition. Examples of the leveling agent are the same as those of the leveling agent in the first aspect.

The total content of the sensitizer and the leveling agent is preferably 20% by mass or less, more preferably 10% by mass or less, based on the total amount of the composition, from the viewpoint of reducing the amount of low molecular weight components and reducing the damage to the device.

Physical Properties of Composition

Viscosity

As described above, the viscosity of the composition of the present aspect measured by using an E-type viscometer at 25° C. and 20 rpm is 5 to 50 mPa·s, preferably 5 to 30 mPa·s, and more preferably 10 to 20 mPa s. A viscosity in the above ranges is more likely to improve the ejection property during the application of the composition by the inkjet method.

Chloride Ion Concentration

The chloride ion content of the composition of the present aspect is 50 ppm or less, preferably 30 ppm or less, and more preferably 10 ppm or less. When the chloride ion concentration of the composition is 50 ppm or less, ion migration is less likely to occur over a long period of time in the semiconductor device that includes the cured product of the composition, thereby minimizing the corrosion of the semiconductor device. The method for measuring the chloride ion concentration in the composition is the same as the method described in the first aspect.

Surface Tension

The surface tension of the composition of the present aspect is preferably 20 to 40 mN/m, more preferably 25 to 40 mN/m, and even more preferably 25 to 35 mN/m. Surface tension is a value measured by the Wilhelmy method at 25° C. Surface tension of the composition of 40 mN/m or less allows easier leveling during the application of the composition by the inkjet method, and thus the composition can evenly coat, for example, the circuit of a semiconductor circuit board. On the other hand, when the surface tension of the composition is 20 mN/m or more, the composition is less likely to spread to wet the surface excessively during the application of the composition by the inkjet method, thereby maintaining the desired thickness and pattern.

Oxygen Content

The oxygen content of the composition is preferably 15% or more, more preferably 20% or more, from the viewpoint of reducing damage to the inkjet device also in the present aspect. On the other hand, the oxygen atom content of the composition is preferably 30% or less. The oxygen atom content of the composition can be calculated from the following formula: (Total mass of oxygen atoms contained in the composition/Total mass of the composition×100(%). The total mass of oxygen atoms contained in the composition can be calculated by the method described in the first aspect.

Physical Properties of Cured Product

The loss tangent (tan δ) of the cured product of the composition at 25° C. to 150° C., obtained by dynamic viscoelasticity measurement at a frequency of 1.6 Hz (10 rad/s), is preferably 0.01 or more, more preferably 0.03 or more, and even more preferably 0.05 or more. The above values are determined by the measurement after irradiating the composition with light having a wavelength of 395 nm at 500 mJ/cm² and further curing the composition at 23° C. for 30 minutes. When the loss tangent (tan δ) of the cured product is within the above ranges, ion migration is less likely to occur.

The storage elastic modulus E′ of the cured product at 85° C., obtained by dynamic viscoelasticity measurement at a frequency of 1.6 Hz (10 rad/s), is preferably 1×10⁶ Pa to 1×10¹⁰ Pa, more preferably 1×10⁷ Pa to 1×10¹⁰ Pa. The loss tangent (tan δ) under this condition is preferably 0.03 or more, more preferably 0.05 or more.

When a cured product whose storage elastic modulus and the loss tangent at 85° C. are within the above ranges is used for a repassivation layer or the like of a semiconductor device, the repassivation layer or the like is more likely to sufficiently absorb impact even in a high temperature environment.

In addition, the peak of the loss tangent (tan δ) of the cured product, obtained by dynamic viscoelasticity measurement at a frequency of 1.6 Hz (10 rad/s), is in the range of preferably 50° C. to 200° C., more preferably 100° C. to 200° C., and even more preferably 120° C. to 200° C. When the peak of the loss tangent is within the above ranges, ion migration is less likely to occur.

The viscosity of the above composition measured at 25° C. and 20 rpm by using an E-type viscometer after irradiating the composition with light having a wavelength of 395 nm at 23° C. and 500 mW/cm² is preferably 50 mPa·s or more, more preferably 70 mPa·s or more. When the viscosity after irradiation with light is within the above ranges, the shape of the composition is less likely to change after the irradiation with light, allowing easier maintaining of a desired shape.

Method for Preparing Composition

The composition can be obtained by mixing the alicyclic epoxy compound (a) having two or more epoxy groups per molecule, the photocationic polymerization initiator (b), the silane coupling agent (c), and thermal amine generator (f), and one or more additional components as necessary by using a mixer such as a homodisper, a homomixer, a universal mixer, a planetary mixer, a kneader, or a three roll mixer.

2. Semiconductor Device

The semiconductor device of the present invention may have any configuration, as long as a part of the semiconductor device (for example, semiconductor circuit or metal wiring) is covered by the cured product (cured product layer) of the inkjet coating-type wiring protection composition described above. When a cured product layer is formed from the composition of the first aspect, the cured product layer contains at least a polymer of the photocationically polymerizable compound (A), and a silane coupling agent (C). When a cured product layer is formed from the composition of the second aspect, the cured product layer contains at least a polymer of the alicyclic epoxy compound (a), and a silane coupling agent (c).

The semiconductor device may be, for example, a device (first embodiment) including the following: a semiconductor circuit board provided with a circuit on at least one surface of the semiconductor circuit board; a cured product layer of an inkjet coating-type wiring protection composition—the cured product layer covers at least a part of the circuit of the semiconductor circuit board; and a semiconductor mold resin layer disposed on or above the cured product layer. Alternatively, the semiconductor device may be a device (second embodiment) including the following: a board (substrate) with metal wiring disposed thereon; a cured product layer of an inkjet coating-type wiring protection composition—the cured product layer covers at least a part of the metal wiring of the board; and a wiring portion disposed on or above the cured layer so as to be electrically connected to the metal wiring. Hereinafter, each embodiment will be described.

### First Embodiment

The semiconductor device of the first embodiment includes at least a semiconductor circuit board, a cured product layer of the inkjet coating-type wiring protection composition, and a semiconductor mold resin layer, and may additionally include other components as necessary.

The semiconductor circuit board may be a board on which a desired circuit is formed on one surface or both surfaces of the board. For example, structures with various circuits (metal wiring) formed on various boards are possible. The type of board is not limited, and, for example, a known board made of, for example, SiON, SiN, or SiO₂ may be used. Further, the material and pattern of the circuit (metal wiring) are not limited, and a circuit made of a metal, such as copper, used in a common semiconductor device can be used.

The cured product layer of the inkjet coating-type wiring protection composition, which is disposed on or above the semiconductor circuit board, is a layer obtained by applying and curing the inkjet coating-type wiring protection composition described above. When the circuit is formed on either side of the semiconductor circuit board, the cured product layer may be formed on either side. The cured product layer may, for example, function as an insulating layer to prevent electrical conduction between the circuit and other members, or may function as a protective layer to prevent corrosion or breakage of the circuit. In particular, forming a cured product layer between the semiconductor circuit board and the mold resin allows the cured product layer to serve as a cushion to protect the circuit from impact.

The shape of the cured product layer is appropriately selected according to the type and application of the semiconductor device. For example, the cured product layer may cover the entire circuit formed on the semiconductor circuit board, or may cover only a part of the circuit.

The cured product layer may have any thickness as long as the cured product layer can sufficiently protect a circuit on the semiconductor circuit board by absorbing impact or insulate the circuit. For example, the thickness is preferably 5 to 20 μm, more preferably 5 to 15 μm. When the composition of the first aspect is used, the thickness is even more preferably 5 to 10 μm, and when the composition of the second aspect is used, the thickness is even more preferably 10 to 15 μm.

The semiconductor mold resin layer is disposed on or above the cured product layer, and the shape of the layer is appropriately selected according to the type and application of the semiconductor device. The semiconductor mold resin layer may be disposed in a pattern on or above the cured product layer, or may be disposed so as to cover the entire surface of the cured product layer. A known mold resin layer of a semiconductor device can be used as the semiconductor mold resin layer.

The semiconductor device of the present embodiment can be produced by various method, such as a method including the following steps: 1) preparing a semiconductor circuit board that includes a circuit formed on at least one surface of the semiconductor circuit board; 2) applying the inkjet coating-type wiring protection composition on the circuit of the semiconductor circuit board by an inkjet method; 3) photo curing of curing a coating film of the inkjet coating-type wiring protection composition by irradiating the coating film with active light within 60 seconds after the applying step; and 4) thermal curing of curing the coating film after the photo curing step with heat. The method may further include a step of forming a semiconductor mold resin layer, as necessary.

The preparing step 1) is a step of preparing the above-described semiconductor circuit board, and may be, for example, a step of forming a circuit on any one of various boards by a known method (for example, a sputtering method).

The applying step 2) is a step of applying an inkjet coating-type wiring protection composition on the circuit of the semiconductor circuit board by an inkjet method. The inkjet device that can be used for applying the inkjet coating-type wiring protection composition may be any known device that includes an ink tank, an inkjet recording head, a drive mechanism for the inkjet recording head, and the like. The type of the inkjet recording head is not limited, and for example, either a piezo type or a valve type may be used. The conditions during the application are not limited and appropriately selected according to the thickness and pattern of the cured product layer.

The photo curing step 3) is, within 60 seconds from the end the applying step, a step of curing the coating film of the inkjet coating-type wiring protection composition by irradiating the coating film with active light. The photo curing step is preferably performed within 10 seconds from the end of the applying step. The type of active light used in the photo curing step is not limited and is appropriately selected according to the type of photocationic polymerization initiator described above, but ultraviolet light is usually used. The light source used for irradiation is also not limited, and examples thereof include known light sources such as xenon lamps, carbon arc lamps, and UV-LED light sources.

The irradiation amount of the active light may be any amount as long as the inkjet coating-type wiring protection composition can be cured with no change in the shape of the coating film thereof occurred after the irradiation with the active light. For example, when light having a wavelength of 300 to 400 nm is used, the integrated light amount of 300 to 3,000 mJ/cm² can cure the coating film of the inkjet coating-type wiring protection composition.

The thermal curing step 4) is a step of further curing the coating film with heat after the photo curing step. Performing the thermal curing step can sufficiently cure the coating film of the inkjet coating-type wiring protection composition. The heating temperature is preferably 80 to 180° C., more preferably 100 to 150° C. The heating time is preferably 10 to 60 minutes, more preferably 10 to 30 minutes.

### Second Embodiment

The semiconductor device of the second embodiment includes at least a board with metal wiring disposed thereon, a cured product of an inkjet coating-type wiring protection composition, and a wiring portion, and may additionally include other components as necessary. Various circuits are typically disposed on the board with metal wiring disposed thereon. In the present embodiment, the metal wiring may be disposed on only one surface of such a board, or the metal wiring may be disposed on the both surfaces. The pattern of the metal wiring is appropriately selected according to the type and application of the semiconductor device.

The cured product layer of the inkjet coating-type wiring protection composition, which is disposed on the metal wiring, is a layer obtained by applying and curing the inkjet coating-type wiring protection composition described above. The cured product layer is for protecting the metal wiring or the like from impact or the like, and functions as a so-called repassivation layer or the like. The shape of the cured product layer is appropriately selected according to the type and application of the semiconductor device. The cured product layer may have a through hole or the like for electrically connecting the metal wiring and the wiring portion.

The cured product layer may have any thickness as long as the cured product layer can sufficiently protect a circuit on the semiconductor circuit board by absorbing impact or insulate the circuit. For example, the thickness is preferably 5 to 20 μm, more preferably 5 to 15 μm. When the composition of the first aspect is used, the thickness is even more preferably 5 to 10 μm, and when the composition of the second aspect is used, the thickness is even more preferably 10 to 15 μm.

The structure and type of wiring portion disposed on or above the cured product layer are appropriately selected according to the type and application of semiconductor device. The wiring portion may constitute various circuits. For example, disposing a conductive path on the metal wiring exposed in the region where the cured product layer is not formed can connect the metal wiring on the board side with the various wiring portions disposed on the cured product layer.

The semiconductor device of the present embodiment can be produced by various method, such as a method including the following steps: 1) preparing a board with metal wiring disposed on at least one surface of the board; 2) applying the inkjet coating-type wiring protection composition in a desired pattern on the metal wiring of the board by an inkjet method; 3) photo curing of curing a coating film of the inkjet coating-type wiring protection composition by irradiating the coating film with active light within 60 seconds after the applying step; and 4) thermal curing of curing the coating film after the photo curing step with heat. The method may further include a step of forming a wiring portion, as necessary.

The preparing step 1) is a step of preparing a board including metal wiring, and may be, for example, a step of forming metal wiring on a semiconductor circuit board in a desired pattern by a known method.

The applying step 2) is a step of applying the inkjet coating-type wiring protection composition on the metal wiring of the board by an inkjet method. The inkjet device used for applying the inkjet coating-type wiring protection composition is the same as the inkjet device used in the first embodiment. The application conditions of the inkjet coating-type wiring protection composition are not limited, and are appropriately selected according to the thickness and pattern of the cured product layer.

The photo curing step 3) is, within 60 seconds from the end the applying step, a step of curing the coating film of the inkjet coating-type wiring protection composition by irradiating the coating film with active light. The photo curing step is preferably performed within 10 seconds from the end of the applying step. The type of active light is not limited and is appropriately selected according to the type of photocationic polymerization initiator described above, but ultraviolet light is usually used. Examples of light sources used for irradiation include known light sources such as xenon lamps, carbon arc lamps, and UV-LED light sources. The irradiation amount of the active light may be any amount as long as the inkjet coating-type wiring protection composition can be cured with no change in the shape of the coating film thereof occurred after the irradiation with the active light. For example, irradiating with light having a wavelength of 300 to 400 nm at the integrated light amount of 300 to 3,000 mJ/cm² sufficiently cures the coating film.

The thermal curing step 4) is a step of further curing the coating film with heat after the photo curing step. Performing the thermal curing step can sufficiently cure the coating film of the inkjet coating-type wiring protection composition. The heating temperature is preferably 80 to 180° C., more preferably 100 to 150° C. The heating time is preferably 10 to 60 minutes, more preferably 10 to 30 minutes.

### EXAMPLES

The present invention will be described in detail based on examples, but the present invention is not limited to these examples.

A. First Aspect

### A-1. Material

### Photocationically Polymerizable Compound (A)

THI-DE (manufactured by JX-TG, 3,4:7,8-Diepoxybicyclo[4.3.0]nonane represented by the following structural formula)

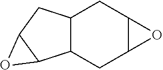 [SMILES: C1C2CC3OC3C2CC2OC12]

OXT-221 (manufactured by Toagosei Co., Ltd., 3-Ethyl-3{[(3-ethyloxetane-3-yl)methoxy]methyl}oxetane, represented by the following formula)

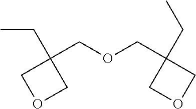

CEL-2021P (manufactured by Daicel Corporation, 3′,4′-Epoxycyclohexylmethyl 3,4-epoxycyclohexanecarboxylate, represented by the following formula)

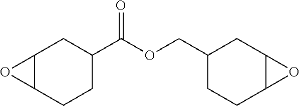 [SMILES: O=C(OCC1CCC2OC2C1)C1CCC2OC2C1]

Photocationic Polymerization Initiator (B)
CPI-210S (manufactured by San-Apro Ltd.)

Silane Coupling Agent (C)
KBM-303 (manufactured by Shin-Etsu Chemical Co., Ltd., 2-(3,4-Epoxycyclohexyl)ethyltrimethoxysilane)
KBM-403 (manufactured by Shin-Etsu Chemical Co., Ltd., 3-Glycidoxypropyltriethoxysilane)
KR-516 (manufactured by Shin-Etsu Chemical Co., Ltd., Epoxy group-containing alkoxy oligomer)
KR-517 (manufactured by Shin-Etsu Chemical Co., Ltd., Epoxy group-containing alkoxy oligomer)

A-2. Preparation of Inkjet Coating-Type Wiring Protection Composition

### Example A-1

A photocationically polymerizable compound (A), a photocationic polymerization initiator (B), and a silane coupling agent (C) at amounts shown in Table 1 were placed in a flask and mixed. The resulting mixture was stirred until no powder was visible to obtain an inkjet coating-type wiring protection composition.

### Examples A-2 to A-6 and Comparative Examples A-1 and A-2

Each inkjet coating-type wiring protection composition was obtained in the same manner as in Example A-1 except that the amounts of the components were changed so as to have the composition shown in Table 1.

Evaluation

For the obtained inkjet coating-type wiring protection compositions, the methods described below were used to evaluate the chloride ion content, viscosity, surface tension, patterning retention, adhesion after pressure cooker test (PCT), ion migration resistance, and loss tangent (tan δ). Table 1 shows the results.

Chloride Ion Content

An inkjet coating-type wiring protection composition was collected in a pressure-resistant container made of polytetrafluoroethylene (PTFE) and weighed, then 10 mL of pure water was added, and the container was sealed tightly. Chlorine was then heat extracted in an oven at 100° C. (set temperature) for 20 hours. The extract was allowed to cool to room temperature, and was then recovered to perform quantitative analysis of chloride ions by an ion chromatograph method (IC method) with the use of an analyzer (IC. ICS-3000, manufactured by Thermo Fisher Scientific). Further, although not shown in Table 1, the quantitative analysis of the contents of fluoride ions and bromine ions was also performed in the same manner to found that both of the contents were 50 ppm or less.

Viscosity

The viscosity was measured at 25° C. and 20 rpm by using an E-type viscometer.

Surface Tension

The surface tension was measured at 25° C. by the Wilhelmy method.

Patterning Retention

An ink tank of an inkjet device was filled with an inkjet coating-type wiring protection composition. The inkjet device was used to apply the inkjet coating-type wiring protection composition to a copperplate and to a 10 cm square SiON sputtered glass. The application pattern was a 5 cm square. The application was performed in such a way that the application amount was 7 pL/drop and the application interval between drops was 30 μm to have a film thickness of 10 μm.

Within 60 seconds after the inkjet coating-type wiring protection composition was applied, the obtained coating film was irradiated with ultraviolet light (wavelength: 365 nm, irradiation light amount: 1,000 mJ/cm²). The coating film was then heated at 150° C. for 30 minutes for thermally curing to form a film with a thickness of 10 μm. The shape of the cured film after the thermal curing was visually checked and evaluated as follows:

Good: The change of application pattern on each side after thermal curing was within ±5%.

Fair: The change of application pattern on each side after thermal curing was beyond ±5% and within ±10%.

Poor: The change of application pattern on each side after thermal curing was beyond ±10%.

Adhesion after Pressure Cooker Test (PCT)

An ink tank of an inkjet device was filled with an inkjet coating-type wiring protection composition. The inkjet device was used to apply the inkjet coating-type wiring protection composition to a copper plate and to SiON sputtered glass. The application pattern was a 5 cm square. The application was performed in such a way that the application amount was 7 pL/drop and the application interval between drops was 30 μm to have a film thickness of 10 μm.

Within 60 seconds after the inkjet coating-type wiring protection composition was applied, the obtained coating film was irradiated with ultraviolet light (wavelength: 365 nm, irradiation light amount: 1,000 mJ/cm²). The coating film was then heated at 150° C. for 30 minutes for thermally curing to form a film with a thickness of 10 μm.

The obtained test piece was stored in highly accelerated stress test system (EHS-222, manufactured by ULVAC, Inc.) at 121° C. and 100% Rh for 96 hours to perform the pressure cooker test (PCT). A grid pattern peeling test (cross-cut test) was then performed in accordance with ISO 2409 to evaluate the adhesion of the cured film according to the following criteria:

Good: Number of remaining squares was 95 to 100/100.

Fair: Number of remaining squares was 50 to 94/100.

Poor: Number of remaining squares was 0 to 49/100

Ion Migration Resistance

An inkjet coating-type wiring protection composition was applied to a board including a comb-shaped electrode and cured in the same manner as in the case of the evaluation of the patterning retention. The board was subjected to a test under the conditions below by using an Electro-chemical migration evaluation system (AMI, manufactured by ESPEC CORP). The resistance value between the electrodes was measured and evaluated as described below.

Test Condition
Temperature: 130° C.
Humidity: 85% RH
Voltage between electrodes: 10V
Test duration: 96 hours

Evaluation Criteria

Good: The resistance value between electrodes was more than 1×10⁵Ω

Poor: The resistance value between electrodes was 1×10⁵Ω or less

Measurement of Loss Tangent (tan δ)

Irradiation with light having a wavelength of 395 nm at 450 mW/cm² and curing at 150° C. for 30 minutes were performed to a coating film of the inkjet coating-type wiring protection composition. The loss tangent (tan δ) at 25° C. to 150° C. was then checked when dynamic viscoelasticity measurement (measuring device: DM6100 manufactured by Seiko Instruments Inc.) was performed at a frequency of 1.6 Hz.

TABLE 1

| | | | | Ex. | | | | | | Comp. Ex. | |
|---|---|---|---|---|---|---|---|---|---|---|---|
| | | | | A-1 | A-2 | A-3 | A-4 | A-5 | A-6 | A-1 | A-2 |
| Composition | (A) Photocationically | THI-DE | parts by mass | 50 | 50 | 50 | 50 | 50 | 50 | 50 | 67 |
| | polymerizable | (Alicyclic epoxy compound) | | | | | | | | | |
| | compound | OXT-221 | parts by mass | 10 | 10 | 10 | 10 | 10 | 10 | 10 | 13 |
| | | (Oxetane compound) | | | | | | | | | |
| | | CEL-202 IP | parts by mass | 40 | 40 | 40 | 40 | 40 | 40 | 40 | 20 |
| | | (Alicyclic epoxy compound) | | | | | | | | | |
| | (B) Photocationic | CPI-210S | parts by mass | 0.5 | 0.5 | 0.5 | 0.5 | 0.5 | 0.5 | 0.5 | 0.5 |
| | polymerization | | | | | | | | | | |
| | initiator | | | | | | | | | | |
| | (C) Silane coupling | KBM-303 | parts by mass | 20 | | | | 3 | 50 | | 55 |
| | agent | KBM-403 | parts by mass | | 20 | | | | | | |
| | | KR-516 | parts by mass | | | 20 | | | | | |
| | | KR-517 | parts by mass | | | | 20 | | | | |

| | | | | | | | | | |
|---|---|---|---|---|---|---|---|---|---|
| Evaluation | Chloride ion content [ppm] | <10 | <10 | <10 | <10 | <10 | <10 | <10 | <10 |
| | Viscosity at 25° C. [mPa · s] | 11 | 11 | 11 | 11 | 10 | 13 | 13 | 11 |
| | Surface tension [mN/m] | 34 | 32 | 32 | 33 | 35 | 30 | 38 | 30 |
| | Patterning retention (Shrinkage when thermally | Good | Good | Good | Good | Good | Fair to | Fair | Poor |
| | cured at 150° C. for 30 minutes) | | | | | | Good | | to Fair |
| | PCT (121° C. × l00% RH × 96 hr) resistance (cross-cut test) | Good | Good | Good | Good | Fair to | Good | Poor | Good |
| | | | | | | Good | | | |
| | Ion migration resistance (130° C. × 85% RH × 10 V × 96 hr) | Good | Good | Good | Good | Good | Good | Poor | Poor |
| | Loss tangent (tan δ): All areas from 25 to 150° C. | >0.05 | >0.05 | >0.05 | >0.05 | >0.05 | >0.05 | >0.05 | >0.05 |

As shown in Table 1, ion migration was less likely to occur and the ejection property by inkjet was excellent in an inkjet coating-type wiring protection composition that contains 1 to 50 parts by mass of the silane coupling agent (C) based on 100 parts by mass of the photocationically polymerizable compound (A) and has a viscosity of 5 to 50 mPa·s (Examples A-1 to A-6). The amount of the silane coupling agent (C) relative to the photocationically polymerizable compound (A) was sufficiently large for substantially improving the adhesion between the cured film and the board, and thus water or the like was less likely to enter the interface between the cured film and the board. It is considered that ion migration was thus less likely to occur.

On the other hand, when the amount of the silane coupling agent (C) exceeded 50 parts by mass based on 100 parts by mass of the photocationically polymerizable compound (A), the amount of the photocationically polymerizable compound (A) relatively decreased, thereby lowering the patterning retention (Comparative Example A-2). In this case, the ion migration resistance was also lowered due to poor curing.

Further, when the amount of the silane coupling agent (C) based on 100 parts by mass of the photocationically polymerizable compound (A) was less than 1.5 parts by mass, the ion migration resistance was lowered, and the PCT resistance was also lowered (Comparative Example A-1).

B. Second Aspect

B-1. Material

### (a) Alicyclic Epoxy Compound

THI-DE (manufactured by JX-TG, 3,4:7,8-Diepoxybicyclo[4.3.0]nonane represented by the following structural formula)

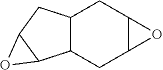 [SMILES: C1C2CC3OC3C2CC2OC12]

Celloxide 2021P (manufactured by Daicel Corporation, 3′,4′-Epoxycyclohexylmethyl 3,4-epoxycyclohexanecarboxylate represented by the following structural formula)

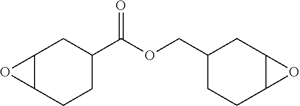 [SMILES: O=C(OCC1CCC2OC2C1)C1CCC2OC2C1]

Photocationic Polymerization Initiator (b)
CPI-210S (manufactured by San-Apro Ltd.)

Silane Coupling Agent (c)
KR-517 (manufactured by Shin-Etsu Chemical Co., Ltd., Epoxy group-containing alkoxy oligomer)

### (d) Additional Component

OXT-221 (manufactured by Toagosei Co., Ltd., 3-Ethyl-3{[(3-ethyloxetane-3-yl)methoxy]methyl}oxetane represented by the following formula)

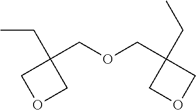

Thermal Amine Generator (f)

The thermal amine generator was obtained by the method described in Japanese Patent Application Laid-Open No. 2017-82208 in which dimethylpyrazole represented by the following general formula (f-1) and Takenate D-170N were reacted to each other at equivalent amounts of amine and isocyanate group.

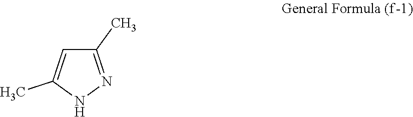

Specifically, at room temperature, 1.00 mol in terms of isocyanate group of polyisocyanate compound (Takenate D-170N), 1.00 mol in terms of amine group of dimethylpyrazole, and 126.913 g of a solvent (methyl isobutyl ketone) were added into a 100 mL reactor equipped with a stirrer, a thermometer, a cooler and a nitrogen gas introduction tube, and the mixture was mixed well. Subsequently, 96.130 g (1.0 mol) of dimethylpyrazole was added in several times so that the temperature of the reaction solution did not exceed 50° C., and the mixture was then stirred at room temperature for 5 hours. Measuring the FT-IR spectrum confirmed that the isocyanate groups were blocked, and a blocked isocyanate (thermal amine generator (f)) having a solid content concentration of 70 mass % was thus obtained.

In a comparative example, an amine-based ion catcher represented by the following structural formula was used in place of the thermal amine generator (f).

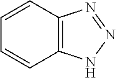

B-2. Preparation of Inkjet Coating-Type Wiring Protection Composition

### Example B-1

An alicyclic epoxy compound (a), a photocationic polymerization initiator (b), a silane coupling agent (c), a thermal amine generator (f), and an oxetane compound (d) (OXT-221) at amounts shown in Table 2 were placed in a flask and mixed. The resulting mixture was stirred until no powder was visible to obtain an inkjet coating-type wiring protection composition.

### Examples B-2 and B-3 and Comparative Examples B-1 and B-2

Each inkjet coating-type wiring protection composition was obtained in the same manner as in Example B-1 except that the amounts of the components were changed so as to have the composition shown in Table 2.

Evaluation

For the obtained inkjet coating-type wiring protection compositions, the methods described below were used to evaluate the photocurability, viscosity, surface tension, patterning retention, adhesion (PCT resistance) after pressure cooker test (PCT), and ion migration resistance. Table 2 shows the results.

Photocurability

As the photocurability, curability when a coating film was cured by irradiation with ultraviolet light (wavelength: 365 nm, irradiation light amount: 1,000 mJ/cm²) within 60 seconds after the application of an inkjet coating-type wiring protection composition was evaluated according to the following criteria:

Good: The coating film was sufficiently cured when examined visually (the composition has no fluidity), and the film was not tacky when touched with a finger.

Poor: The coating film was not sufficiently cured when examined visually (the composition has fluidity), or the film was tacky when touched with a finger.

Viscosity

The viscosity was measured at 25° C. and 20 rpm by using an E-type viscometer.

Surface Tension

The surface tension was measured at 25° C. by the Wilhelmy method.

Patterning Retention

An ink tank of an inkjet device was filled with an inkjet coating-type wiring protection composition. The inkjet device was used to apply the inkjet coating-type wiring protection composition to a copperplate and to a 10 cm square SiON sputtered glass. The application pattern was a 5 cm square. The application was performed in such a way that the application amount was 7 pL/drop and the application interval between drops was 30 μm to have a film thickness of 10 μm.

Within 60 seconds after the inkjet coating-type wiring protection composition was applied, the obtained coating film was irradiated with ultraviolet light (wavelength: 365 nm, irradiation light amount: 1,000 mJ/cm²). The coating film was then heated at 150° C. for 30 minutes for thermally curing to form a film with a thickness of 10 μm. The shape of the cured film after the thermal curing was visually checked and evaluated as follows:

Good: The change of application pattern on each side after thermal curing was within ±5%.

Fair: The change of application pattern on each side after thermal curing was beyond ±5% and within ±10%.

Poor: The change of application pattern on each side after thermal curing was beyond ±10%.

Adhesion (also referred to as “PCT resistance”) after Pressure Cooker Test (PCT)

An ink tank of an inkjet device was filled with an inkjet coating-type wiring protection composition. The inkjet device was used to apply the inkjet coating-type wiring protection composition to a copper plate and to SiON sputtered glass. The application pattern was a 5 cm square. The application was performed in such a way that the application amount was 7 pL/drop and the application interval between drops was 30 μm to have a film thickness of 10 μm.

Within 60 seconds after the inkjet coating-type wiring protection composition was applied, the obtained coating film was irradiated with ultraviolet light (wavelength: 365 nm, irradiation light amount: 1,000 mJ/cm²). The coating film was then heated at 150° C. for 30 minutes for thermally curing to form a film with a thickness of 10 μm.

The obtained test piece was stored in highly accelerated stress test system (EHS-222, manufactured by ULVAC, Inc.) at 121° C. and 100% Rh for 96 hours to perform the pressure cooker test (PCT). A grid pattern peeling test (cross-cut test) was then performed in accordance with ISO 2409 to evaluate the adhesion of the cured film according to the following criteria:

Good: Number of remaining squares was 95 to 100/100.

Fair: Number of remaining squares was 50 to 94/100.

Poor: Number of remaining squares was 0 to 49/100

Ion Migration Resistance

An inkjet coating-type wiring protection composition was applied to a board including a comb-shaped electrode and cured in the same manner as in the case of the evaluation of the patterning retention. The board was subjected to a test under the conditions below by using an Electro-chemical migration evaluation system (AMI, manufactured by ESPEC CORP). The resistance value between the electrodes was measured and evaluated as described below.

Test Condition
Temperature: 130° C.
Humidity: 85% RH
Voltage between electrodes: 10V
Test duration: 96 hours

Evaluation Criteria

Good: No migration occurred during the test. That is, the resistance value between electrodes did not fall below 1×10⁵Ω

Poor: The resistance value between electrodes became 1×10⁵Ω or less

TABLE 2

| | | | | Ex. | | | Comp. Ex. | |
|---|---|---|---|---|---|---|---|---|
| | | | Unit | B-1 | B-2 | B-3 | B-1 | B-2 |
| Composition | (a) Alicyclic | THI-DE | parts by | 50 | 60 | 60 | 60 | 60 |
| | epoxy | | mass | | | | | |
| | compound | CEL2021P | parts by | 40 | 25 | 25 | 25 | 25 |
| | | | mass | | | | | |
| | (b) Photocationic | CPI-210S | parts by | 0.5 | 0.5 | 0.5 | 0.5 | 0.5 |
| | polymerization | | mass | | | | | |
| | initiator | | | | | | | |
| | (c) Silane coupling | KR-517 | parts by | 10 | 10 | 10 | 10 | 10 |
| | agent | | mass | | | | | |
| | (d)Additional | OXT-221 | parts by | 10 | 15 | 15 | 15 | 15 |
| | Components | | mass | | | | | |
| | (f) Thermal amine | F-1 | parts by | 0.5 | 1 | 2 | | |
| | generator | | mass | | | | | |
| | Amine-based | 5-Methyl-lH- | parts by | | | | 0.1 | |
| | ion catcher | benzotriazole | mass | | | | | |
| Evaluation | Photocurability | | | Good | Good | Good | Poor | Good |
| | Viscosity | 25° C. | mPa · s | 11 | 11 | 11 | 11 | 11 |

| | | | | | | |
|---|---|---|---|---|---|---|
| Patterning | Shrinkage when | Good | Good | Good | Poor | Good |
| retention | thermally cured at | | | | | |
| | 150° C. for 30 minutes | | | | | |
| PCT resistance | 121° C. × 100% RH × 96 hr | Good | Good | Good | Poor | Poor |
| (cross-cut test) | | | | | | |
| Ion migration test | 121° C. × 100% RH × 96 hr | Good | Good | Good | Poor | Poor |

As shown in Table 2, ion migration was less likely to occur and the PCT resistance was excellent in an inkjet coating-type wiring protection composition including the thermal amine generator (f), which is an adduct from an amine having a specific structure and an isocyanate (Examples B-1 to B-3). When a common amine-based ion catcher was used, meanwhile, the photocurability was inferior, ion migration was more likely to occur, and the PCT resistance was also inferior (Comparative Example B-1). Further, when the thermal amine generator (f) or the amine-based ion catcher was not used, ion migration was more likely to occur, and the PCT resistance was lowered (Comparative Example B-2).

This application claims priority based on Japanese Patent Application No. 2019-196090, filed on Oct. 29, 2019 and Japanese Patent Application No. 2019-222142 filed on Dec. 9, 2019, the entire contents of which including the specifications are incorporated herein by reference.

### INDUSTRIAL APPLICABILITY

The inkjet coating-type wiring protection composition of the present invention is capable of forming a cured product having excellent pattern retention at high temperatures and moisture resistance and also having suitable adhesion to a semiconductor circuit or the like for a long period of time. In addition, the cured product has excellent ion migration resistance. Further, the inkjet coating-type wiring protection composition of the present invention can be applied by an inkjet method, and thus can be applied efficiently and easily. Therefore, the inkjet coating-type semiconductor protection composition is particularly advantageous for production of protective layers (for example, repassivation layers) and insulating layers of various semiconductor devices and the like.

1. An inkjet coating-type wiring protection composition, comprising:
a photocationically polymerizable compound (A) that contains an alicyclic epoxy compound comprising two or more epoxy groups per molecule;
a photocationic polymerization initiator (B); and
a silane coupling agent (C),
wherein:
the silane coupling agent (C) is contained in an amount of 1 to 50 parts by mass based on 100 parts by mass of the photocationically polymerizable compound (A), and
the inkjet coating-type wiring protection composition has a viscosity of 5 to 50 mPa·s measured at 25° C. and 20 rpm by using an E-type viscometer.

2. The inkjet coating-type wiring protection composition according to claim 1, wherein:
the inkjet coating-type wiring protection composition has a surface tension of 20 to 40 mN/m.

3. The inkjet coating-type wiring protection composition according to claim 1, wherein:
the alicyclic epoxy compound has a cycloalkene oxide structure represented by a general formula below 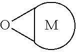
wherein M represents an alicyclic structure comprising 4 to 8 carbon atoms.

4. A cured product of the inkjet coating-type wiring protection composition according to claim 1, wherein:
the cured product has a loss tangent (tan δ) of 0.01 or more in a temperature range of 25° C. to 150° C. when dynamic viscoelasticity measurement is performed at a frequency of 1.6 Hz.

5. A semiconductor device, comprising:
a semiconductor circuit board or a board including metal wiring, the semiconductor circuit board including a circuit on at least one surface thereof; and
a cured product layer that covers the semiconductor circuit board or the metal wiring of the board,
wherein:
the cured product layer contains a polymer and a silane coupling agent, the polymer being a polymer of a photocationically polymerizable compound containing an alicyclic epoxy compound comprising two or more epoxy groups per molecule, and
the silane coupling agent is contained in an amount of 1 to 50 parts by mass based on 100 parts by mass of the polymer.

6. A method for producing a semiconductor device, the method comprising:
preparing a semiconductor circuit board or a board including metal wiring, the semiconductor circuit board including a circuit on at least one surface thereof;
applying the inkjet coating-type wiring protection composition according to claim 1 on the circuit of the semiconductor circuit board or on the metal wiring of the board by an inkjet method;
photo curing of curing a coating film of the inkjet coating-type wiring protection composition by irradiating the coating film with active light within 60 seconds after the applying; and
thermal curing of curing the coating film after the photo curing with heat.

7. An inkjet coating-type wiring protection composition, comprising:
an alicyclic epoxy compound (a) comprising two or more epoxy groups per molecule;
a photocationic polymerization initiator (b);
a silane coupling agent (c); and
a thermal amine generator (f),
wherein
the inkjet coating-type wiring protection composition has chloride ion content of 50 ppm or less,
the inkjet coating-type wiring protection composition has a viscosity of 5 to 50 mPa·s measured at 25° C. and 20 rpm by using an E-type viscometer, and
the thermal amine generator (f) is an adduct from an amine represented by a general formula below and an isocyanate 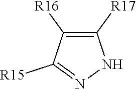
wherein R15, R16, and R17 independently represent a hydrogen atom, an alkyl group, or a phenyl group.

8. The inkjet coating-type wiring protection composition according to claim 7, wherein:
the inkjet coating-type wiring protection composition has a surface tension of 20 to 40 mN/m.

9. The inkjet coating-type wiring protection composition according to claim 7, wherein:
the alicyclic epoxy compound (a) has a cycloalkene oxide structure represented by a general formula below 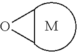
wherein M represents an alicyclic structure comprising 4 to 8 carbon atoms.

10. The inkjet coating-type wiring protection composition according to claim 7, wherein:
based on 100 parts by mass of the alicyclic epoxy compound (a),
the photocationic polymerization initiator (b) is contained in an amount of 0.1 to 10 parts by mass;
the silane coupling agent (c) is contained in an amount of 1 to 50 parts by mass; and
the thermal amine generator (f) is contained in an amount of 0.05 to 5 parts by mass.

11. A cured product of the inkjet coating-type wiring protection composition according to claim 7, wherein:
the cured product has a loss tangent (tan δ) of 0.01 or more in a temperature range of 25° C. to 150° C. when dynamic viscoelasticity measurement is performed at a frequency of 1.6 Hz.

12. A semiconductor device, comprising:
a semiconductor circuit board or a board including metal wiring, the semiconductor circuit board including a circuit on at least one surface thereof; and
a cured product layer that covers the semiconductor circuit board or the metal wiring of the board,
wherein
the cured product layer contains a polymer and a silane coupling agent, the polymer being a polymer of an alicyclic epoxy compound comprising two or more epoxy groups per molecule, and
the cured product layer has chloride ion content of 50 ppm or less.

13. A method for producing a semiconductor device, the method comprising:
preparing a semiconductor circuit board or a board including metal wiring, the semiconductor circuit board including a circuit on at least one surface thereof;
applying the inkjet coating-type wiring protection composition according to any one of claim 7 on the circuit of the semiconductor circuit board or on the metal wiring of the board by an inkjet method;
photo curing of curing a coating film of the inkjet coating-type wiring protection composition by irradiating the coating film with active light within 60 seconds after the applying; and
thermal curing of curing the coating film after the photo curing with heat.
